(19) United States
(12) Patent Application Publication
(10) Pub. No.: US 2025/0318234 A1
(43) Pub. Date: Oct. 9, 2025

(54) SEMICONDUCTOR DEVICE AND FORMATION METHOD THEREOF

(71) Applicant: TAIWAN SEMICONDUCTOR MANUFACTURING COMPANY, LTD., Hsinchu (TW)

(72) Inventors: Fu-Ting YEN, Hsinchu City (TW); Yu-Yun PENG, Hsinchu City (TW); Zheng-Yong LIANG, Kaohsiung City (TW); Kuei-Lin CHAN, Hsinchu (TW)

(73) Assignee: TAIWAN SEMICONDUCTOR MANUFACTURING COMPANY, LTD., Hsinchu (TW)

(21) Appl. No.: 18/626,884

(22) Filed: Apr. 4, 2024

(51) Int. Cl. H01L 29/66; H01L 21/02; H01L 29/06; H01L 29/775; H01L 29/786

(52) U.S. Cl. CPC H10D 64/018; H10D 30/014; H10D 30/031; H10D 30/43; H10D 30/6757; H10D 62/116; H01L 21/0217; H01L 21/02203; H01L 21/02219; H01L 21/0228; H01L 21/02337

(57) ABSTRACT

A method of forming a semiconductor device comprises the following steps. A fin is formed protruding from a substrate. A dummy gate is formed across the fin. Gate spacers are formed on opposite sidewalls of the dummy gate using one or more atomic layer deposition (ALD) cycles. Each of the ALD cycles comprises pulsing a precursor to the dummy gate, after pulsing the precursor to the dummy gate, pulsing a bridging gas to the dummy gate, wherein the bridging gas is ammonia, hydrogen, or a combination thereof, and after pulsing the bridging gas to the dummy gate, pulsing an oxygen-containing gas to the dummy gate. The dummy gate is replaced with a metal gate.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of gate-all-around field-effect transistors (GAA-FETs) in a three-dimensional view, in accordance with some embodiments.

FIGS. 2-5, 6A, 13A, 14A, 15A and 16A are cross-sectional views at intermediate fabrication stages, illustrating reference cross-section A-A′ illustrated in FIG. 1 that extends through a gate region along a longitudinal axis of the gate region.

FIGS. 6B, 7B, 8B, 9B, 10B, 11B, 12B, 13B, 14B, 15B and 16B are cross-sectional views at intermediate fabrication stages, illustrating reference cross-section B-B′ illustrated in FIG. 1 that extends through a fin along a longitudinal axis of the fin.

FIGS. 7A, 8A, 9A, 10A, 11A, 12A, and 13C are cross-sectional views at intermediate fabrication stages, illustrating reference cross-section C-C′ illustrated in FIG. 1 that extends through source/drain regions along the longitudinal direction of the gate region.

FIGS. 7C and 7D illustrate a process of forming the spacer layer in accordance with some embodiments.

FIGS. 7E, 7F and 7G illustrate a process of forming the spacer layer in accordance with some embodiments.

FIG. 7H is some details for depositing the spacer layer using ammonia as the bridging gas.

FIGS. 7I and 7J are some details for depositing the spacer layer using oxygen as the bridging gas.

FIGS. 7K, 7L and 7M illustrate a process of forming the spacer layer in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 230 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. In this disclosure, a source/drain refers to a source and/or a drain. It is noted that in the present disclosure, a source and a drain are interchangeably used and the structures thereof are substantially the same.

To enhance device performance, further reduction in total effective capacitance is desired as device scales down. Low k-value spacers, such as poly pacer or inner spacer may be used to achieve this goal. However, using low k-value materials often results in reduced material density, which may lead to weak etch resistivity. For example, the low k-value materials are designed with enough Si—CH₃ bonding to create space in order to achieve a reduced k-value. However, excessive Si—CH₃ bonding may lead to low plasma resistivity and low etch resistivity. Striking a balance between achieving the desired k-value and maintaining robust plasma resistivity and etch resistivity is required.

Embodiments of the present disclosure provide a precursor with embedded Si—C—Si bonding to combine benefits of low k-value and Si—C—Si bonding. The precursor allows for a reduction in k-value of an as-deposited spacer layer while the Si—C—Si bonding provides desired resistance to etch processes. By incorporating the precursor into the device fabrication process, low capacitance value without sacrificing etch resistivity can be achieved.

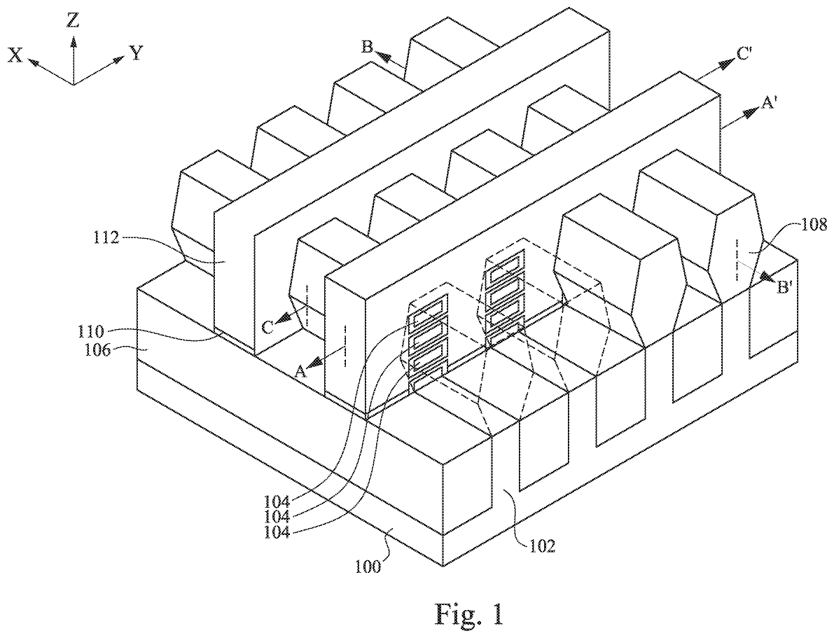

FIG. 1 illustrates an example of GAA-FETs (e.g., nanowire FETs, nanosheet FETs, or the like) in a three-dimensional view, in accordance with some embodiments. As shown, the coordinate system includes an X-axis, Y-axis, and Z-axis. The GAA-FETs comprise nanostructures 104 (e.g., nanosheets, nanowires, nanorings, nanoslabs, or other structures having nano-scale size (e.g., a few nanometers)) over fins 102 on a substrate 100 (e.g., a semiconductor substrate), wherein the nanostructures 104 act as channel regions for the GAA-FETs. The nanostructure 104 may include p-type nanostructures, n-type nanostructures, or a combination thereof. Isolation regions 106 are disposed between adjacent fins 102, which may protrude above and from between neighboring isolation regions 106. Although the isolation regions 106 are described/illustrated as being separate from the substrate 100, as used herein, the term “substrate” may refer to the semiconductor substrate alone or a combination of the semiconductor substrate and the isolation regions. Additionally, although a bottom portion of the fins 102 are illustrated as being single, continuous materials with the substrate 100, the bottom portion of the fins 102 and/or the substrate 100 may comprise a single material or a plurality of materials. In this context, the fins 102 refer to the portion extending between the neighboring isolation regions 106.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Gate dielectrics 110 are over top surfaces of the fins 102 and along top surfaces, sidewalls, and bottom surfaces of the nanostructures 104. Gate electrodes 112 are over the gate dielectrics 110. Epitaxial source/drain regions 108 are disposed on the fins 102 on opposing sides of the gate dielectrics 110 and the gate electrodes 112.

FIG. 1 further illustrates reference cross-sections that are used in later figures. Cross-section A-A′ is along a longitudinal axis of a gate electrode 112 and in a direction, for example, perpendicular to the direction of current flow between the epitaxial source/drain regions 108 of a GAA-FET. That is, the cross-sectional A-A′ is along the y-axis. Cross-section B-B′ is perpendicular to cross-section A-A′ and is parallel to a longitudinal axis of a fin 102 of the GAA-FET and in a direction of, for example, a current flow between the epitaxial source/drain regions 108 of the GAA-FET. That is, the cross-sectional B-B′ is along the x-axis. Cross-section C-C′ is parallel to cross-section A-A′ and extends through epitaxial source/drain regions of the GAA-FETs. That is, the cross-sectional C-C′ is along the y-axis. Subsequent figures refer to these reference cross-sections for clarity.

Some embodiments discussed herein are discussed in the context of GAA-FETs formed using a gate-last process. In other embodiments, a gate-first process may be used. Also, some embodiments contemplate aspects used in planar devices, such as planar FETs or in fin field-effect transistors (FinFETs).

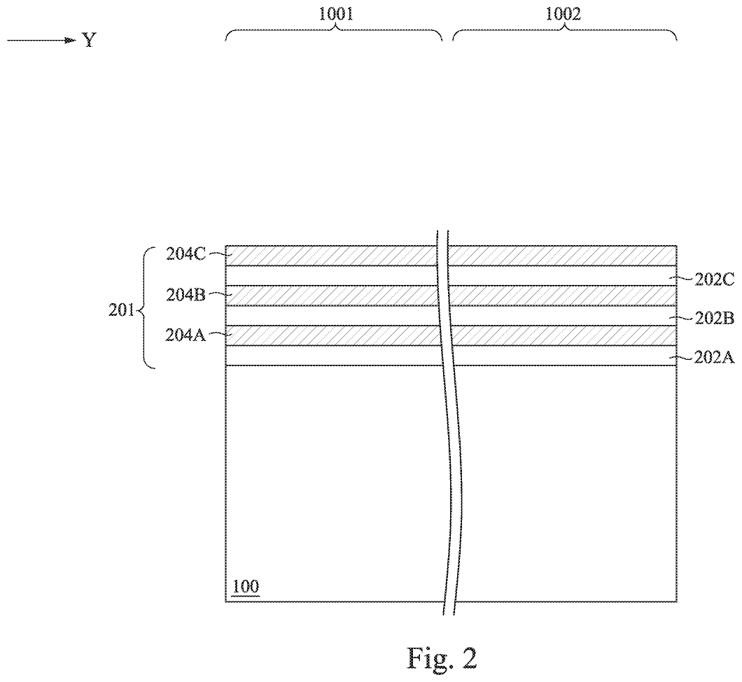

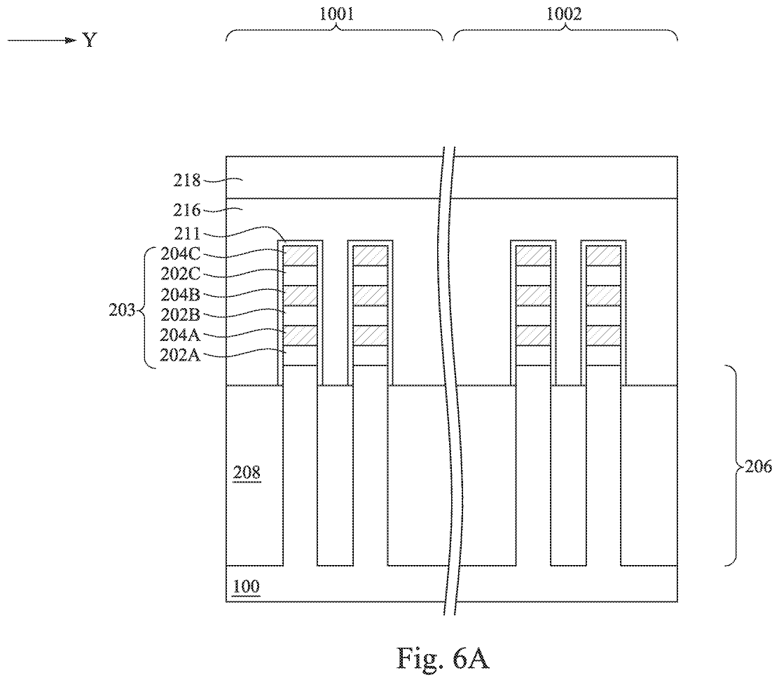

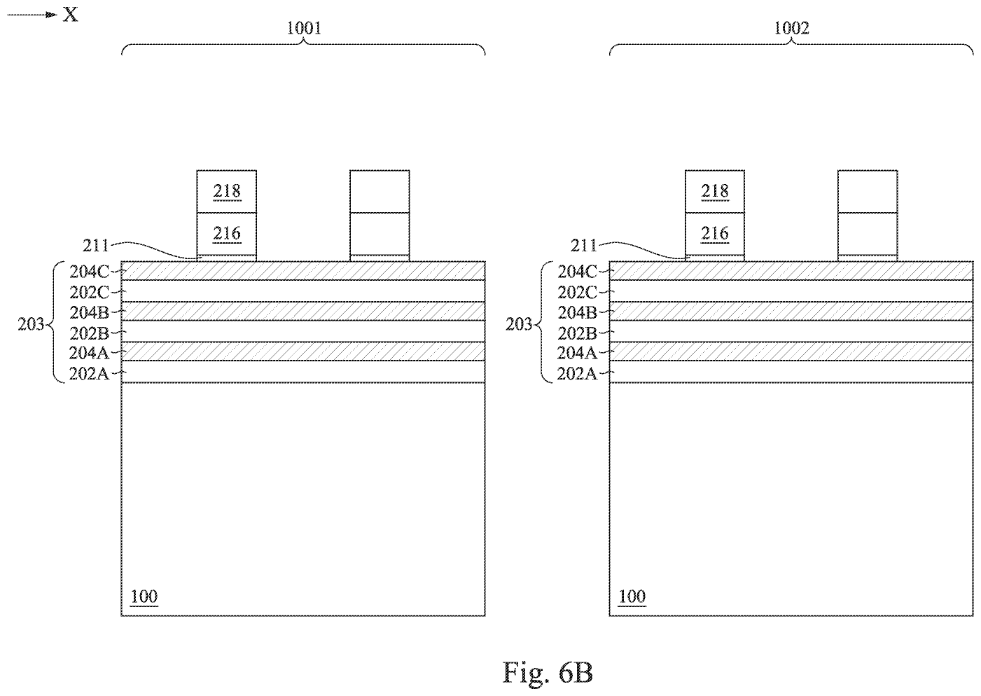

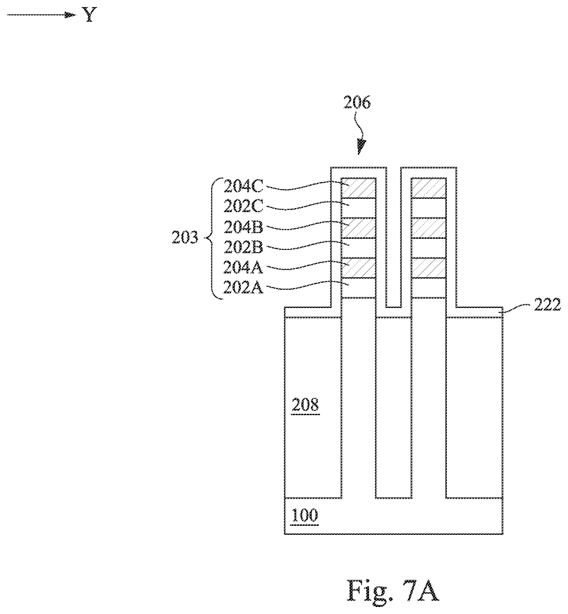

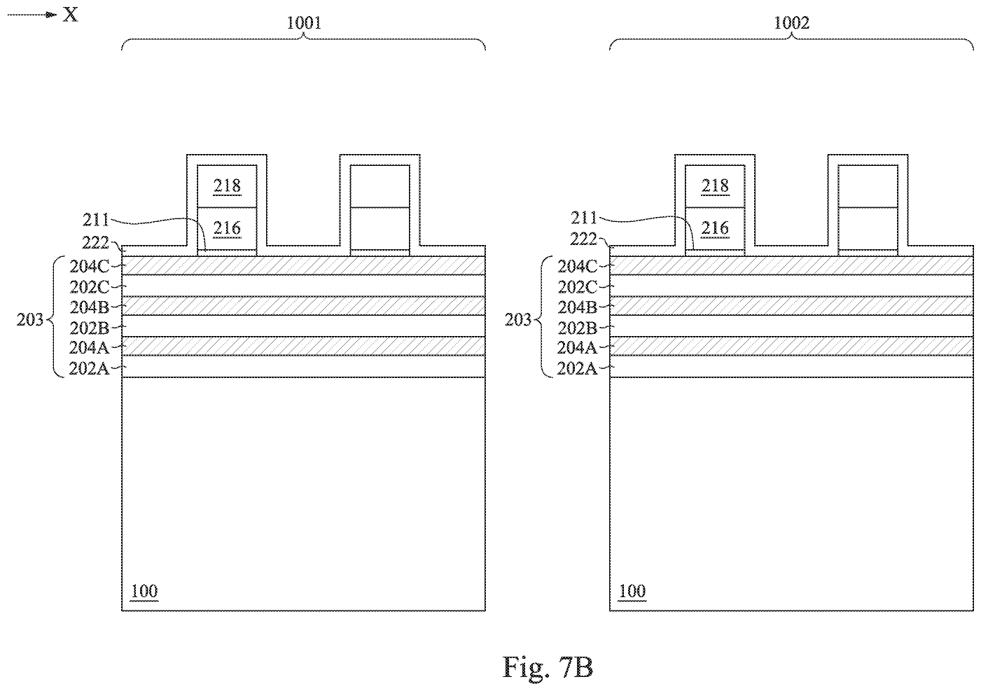

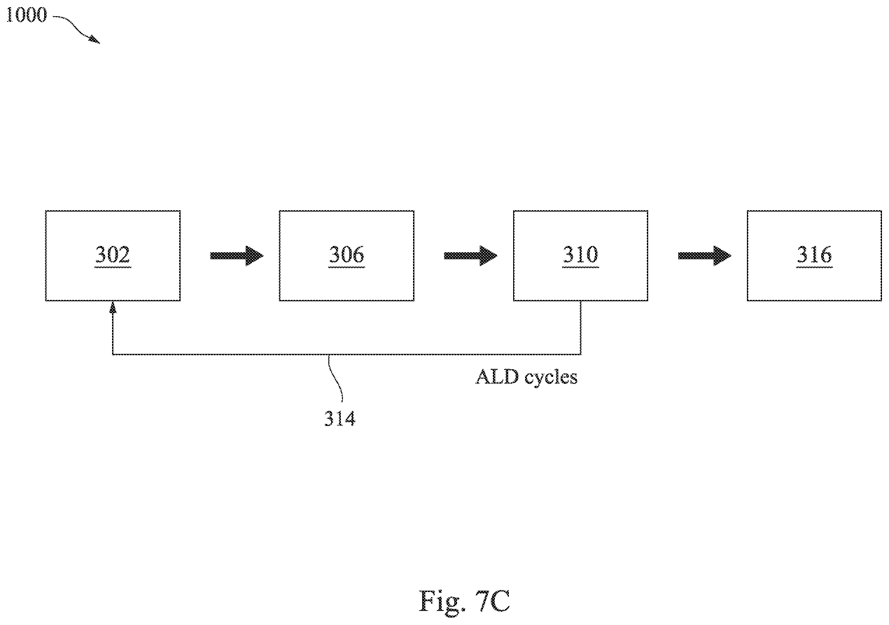

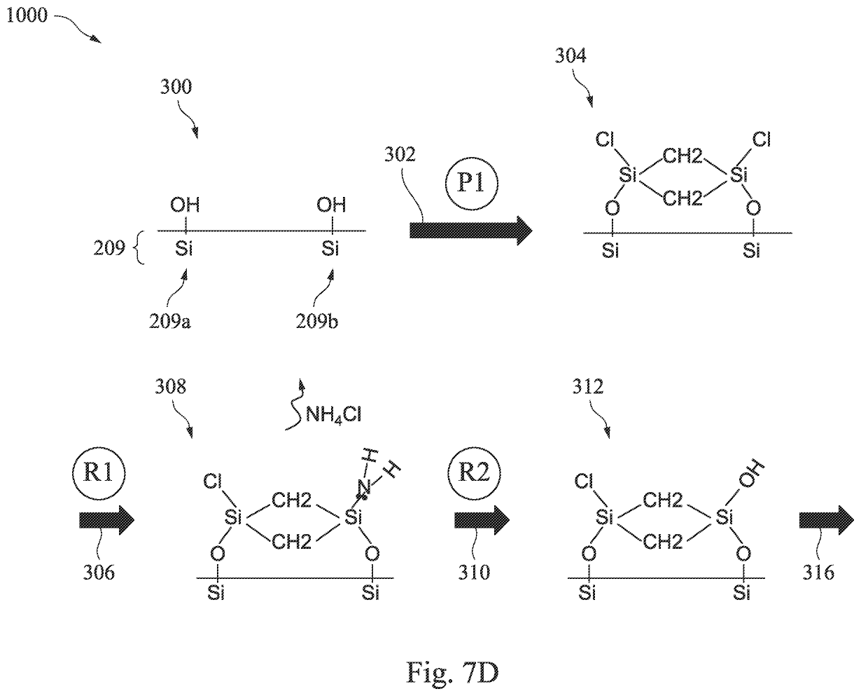

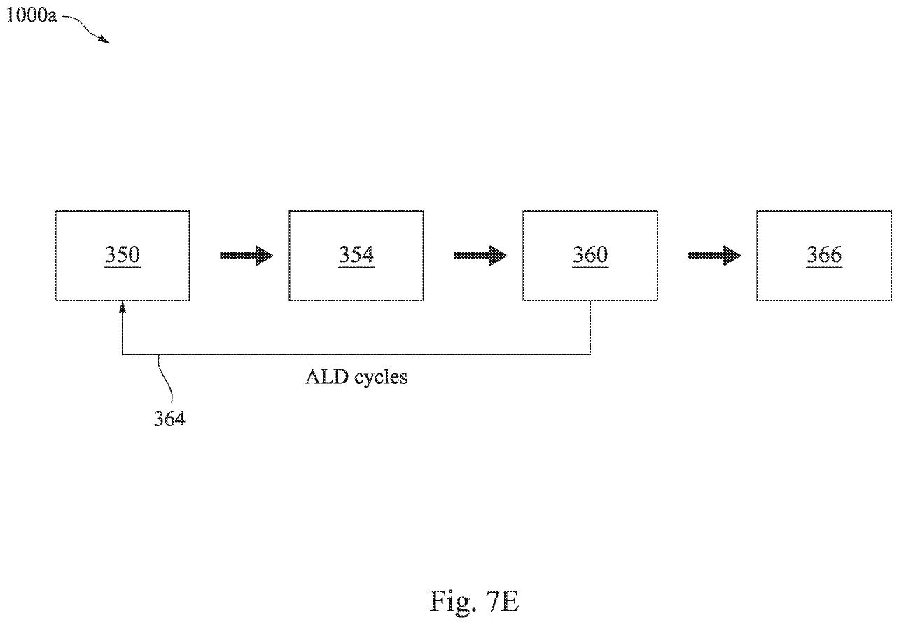

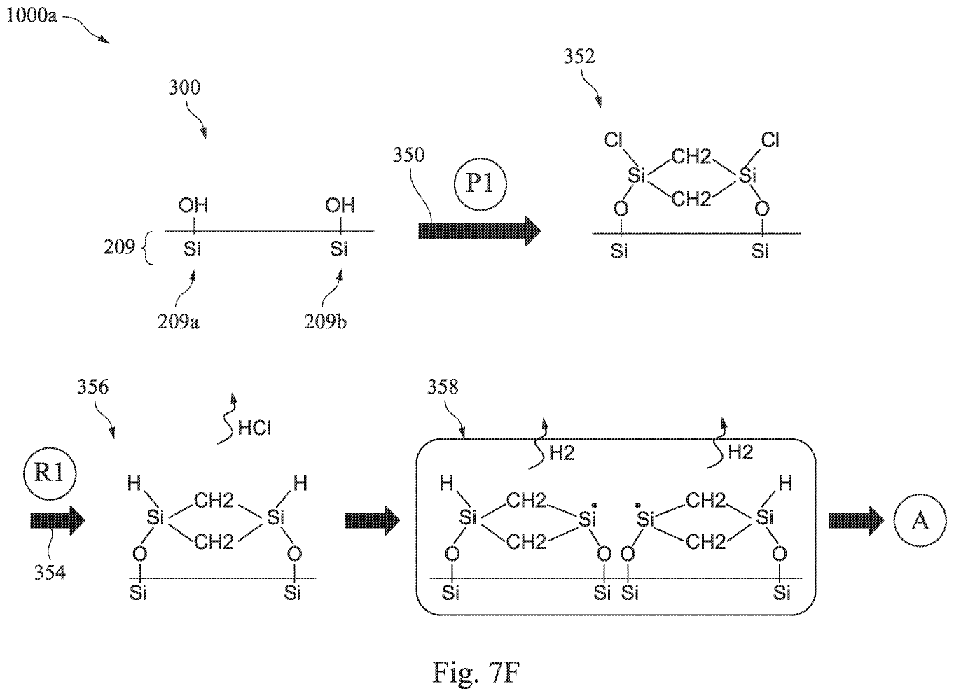

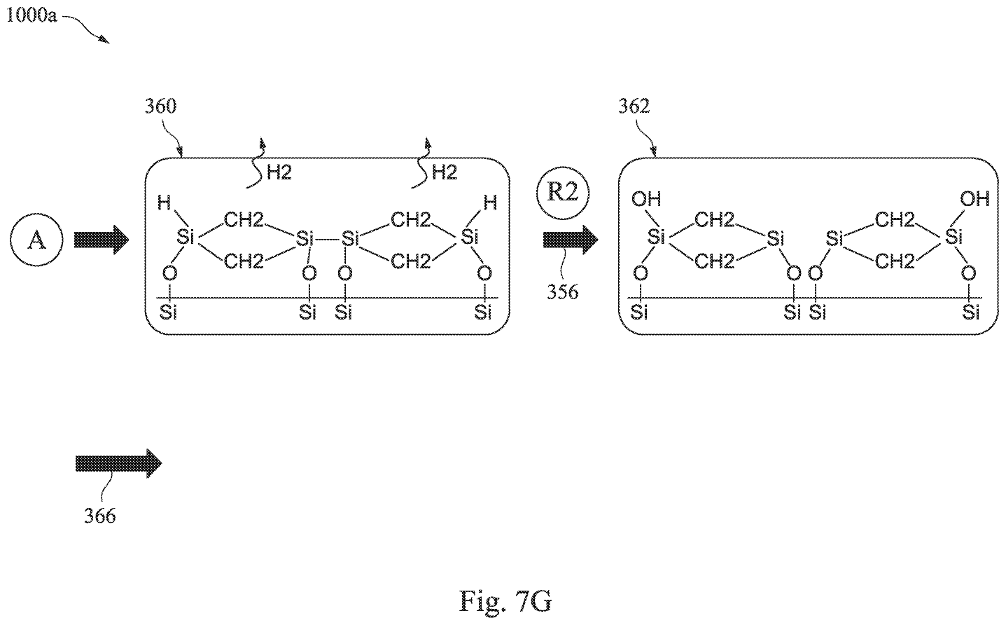

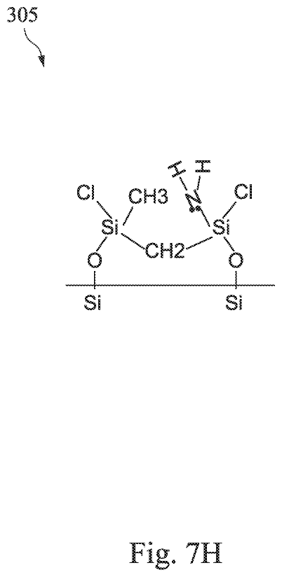

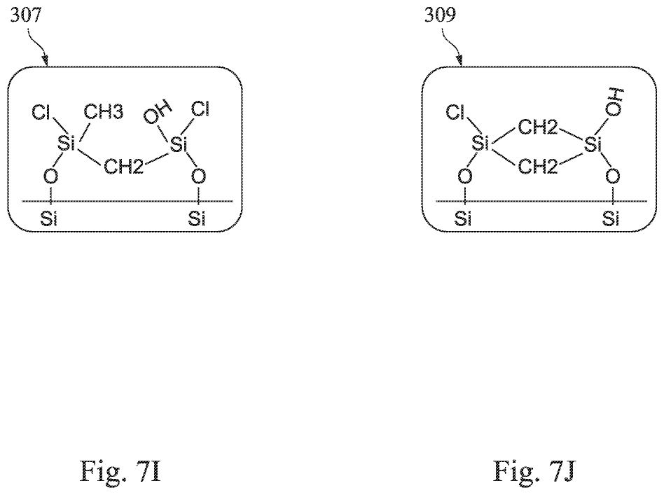

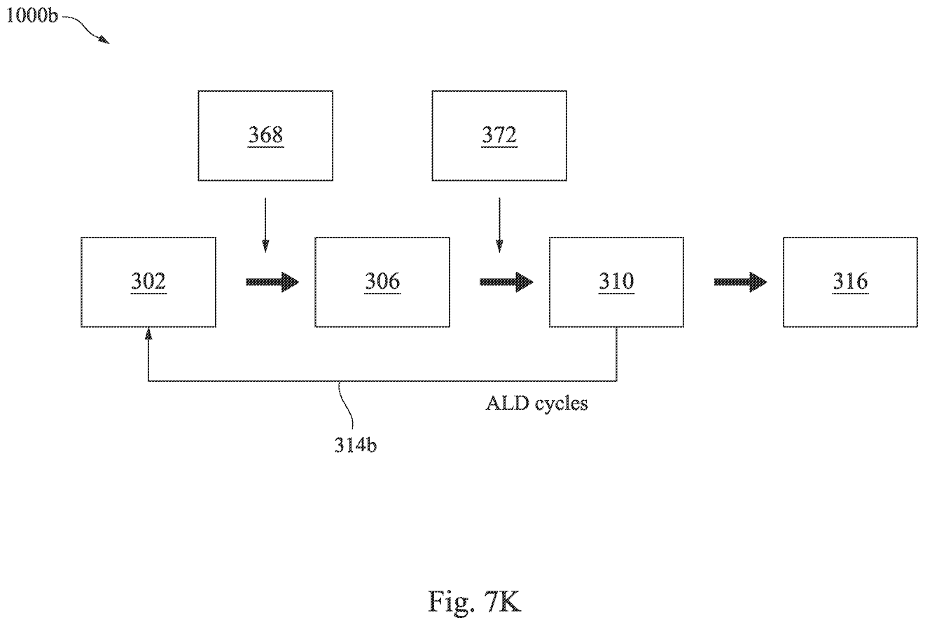

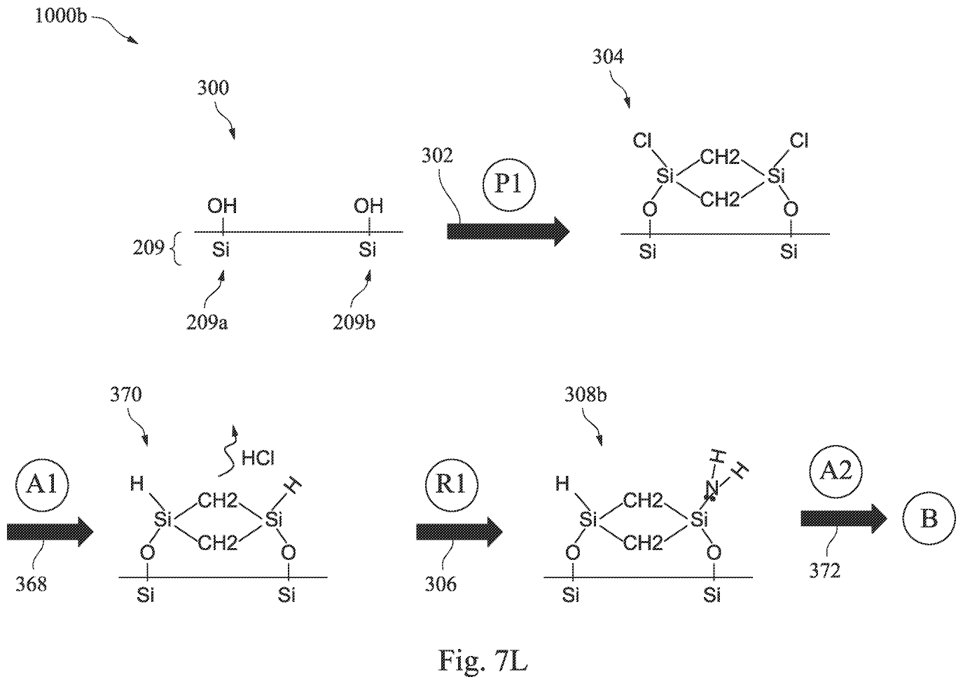

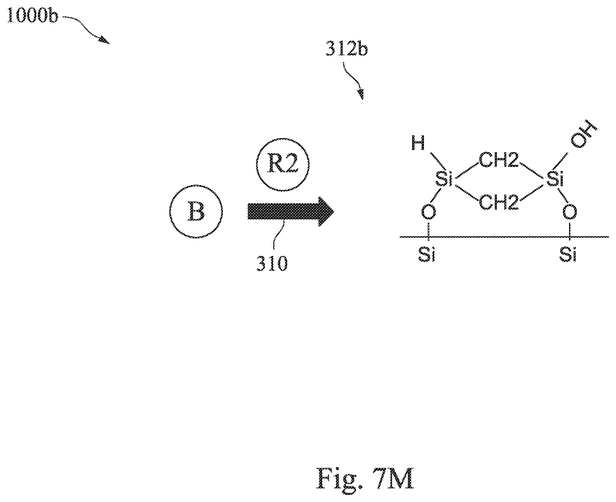

FIGS. 2 through 5, 6A, 13A, 14A, 15A and 16A illustrate reference cross-section A-A′ illustrated in FIG. 1 that extends through a gate region along a longitudinal axis of the gate region. FIGS. 6B, 7B, 8B, 9B, 10B, 11B, 12B, 13B, 14B, 15B and 16B illustrate reference cross-section B-B′ illustrated in FIG. 1 that extends through a fin along a longitudinal axis of the fin. FIGS. 7A, 8A, 9A, 10A, 11A, 12A, and 13C illustrate reference cross-section C-C′ illustrated in FIG. 1 that extends through source/drain regions along the longitudinal direction of the gate region.

In FIG. 2, a substrate 100 is provided. The substrate 100 may be a semiconductor substrate, such as a bulk semiconductor, a semiconductor-on-insulator (SOI) substrate, or the like, which may be doped (e.g., with a p-type or an n-type dopant) or undoped. The substrate 100 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 100 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 100 has a first device region 1001 and a second device region 1002. The first device region 1001 is a region in which first transistors will reside, and the second device region 1002 is a region in which second transistors will reside. In some embodiments, the first transistors are different from the second transistors at least in conductivity type. For example, the first device region 1001 can be for forming n-type devices, such as NMOS transistors, e.g., n-type GAA-FETs, and the second device region 1002 can be for forming p-type devices, such as PMOS transistors, e.g., p-type GAA-FETs. The p-type devices may include a metal gate including a first p-type work function metal layer filling sheet-to-sheet spaces between adjacent nanostructures and a second p-type work function metal layer with thin thickness wrapping the nanostructures, which will be discussed in greater detail below.

The first device region 1001 may be separated from the second device region 1002, and any number of device features (e.g., other active devices, doped regions, isolation structures, etc.) may be disposed between the first device region 1001 and the second device region 1002. Although one first device region 1001 and one second device region 1002 are illustrated, any number of first device regions 1001 and second device regions 1002 may be provided.

Further in FIG. 2, a multi-layer stack 201 is formed over the substrate 100. The multi-layer stack 201 includes alternating layers of first semiconductor layers 202A-C (collectively referred to as first semiconductor layers 202) and second semiconductor layers 204A-C (collectively referred to as second semiconductor layers 204). For purposes of illustration and as discussed in greater detail below, the first semiconductor layers 202 will be removed and the second semiconductor layers 204 will be patterned to form channel regions of GAA-FETs.

The multi-layer stack 201 is illustrated as including three layers of each of the first semiconductor layers 202 and the second semiconductor layers 204 for illustrative purposes. In some embodiments, the multi-layer stack 201 may include any number of the first semiconductor layers 202 and the second semiconductor layers 204. Each of the layers of the multi-layer stack 201 may be epitaxially grown using a process such as chemical vapor deposition (CVD), atomic layer deposition (ALD), vapor phase epitaxy (VPE), molecular beam epitaxy (MBE), or the like. In various embodiments, the second semiconductor layers 204 may be formed of a semiconductor material suitable for serving as channel regions of GAA-FETs, such as silicon, silicon carbon, silicon germanium, or the like.

The first semiconductor materials and the second semiconductor materials may be materials having a high-etch selectivity to one another. As such, the first semiconductor layers 202 of the first semiconductor material may be removed without significantly removing the second semiconductor layers 204 of the second semiconductor material, thereby allowing the second semiconductor layers 204 to serve as channel regions of GAA-FETs.

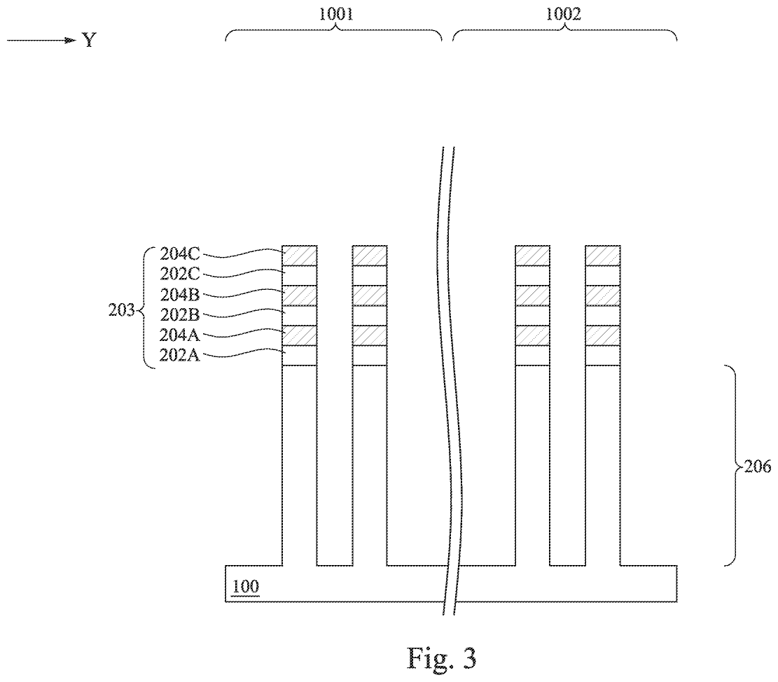

Referring now to FIG. 3, fin structures 206 are formed in the substrate 100 and nanostructures 203 are formed in the multi-layer stack 201, in accordance with some embodiments. In some embodiments, the nanostructures 203 and the fin structures 206 may be formed in the multi-layer stack 201 and the substrate 100, respectively, by etching trenches in the multi-layer stack 201 and the substrate 100. Each fin structure 206 and overlying nanostructures 203 can be collectively referred to as a fin extending from the substrate 100. The etching may be any acceptable etch process, such as a reactive ion etch (RIE), neutral beam etch (NBE), the like, or a combination thereof. The etching may be anisotropic. Forming the nanostructures 203 by etching the multi-layer stack 201 may further define first nanostructures 202A-C (collectively referred to as the first nanostructures 202) from the first semiconductor layers 202 and define second nanostructures 204A-C (collectively referred to as the second nanostructures 204) from the second semiconductor layers 204. The first nanostructures 202 and the second nanostructures 204 may further be collectively referred to as nanostructures 203.

The fin structures 206 and the nanostructures 203 may be patterned by any suitable method. For example, the fin structures 206 and the nanostructures 203 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures 206.

FIG. 3 illustrates the fin structures 206 in the first device region 1001 and the second device region 1002 as having substantially equal widths for illustrative purposes. In some embodiments, widths of the fin structures 206 in the first device region 1001 may be greater or thinner than the fin structures 206 in the second device region 1002. Further, while each of the fin structures 206 and the nanostructures 203 are illustrated as having a consistent width throughout, in other embodiments, the fin structures 206 and/or the nanostructures 203 may have tapered sidewalls such that a width of each of the fin structures 206 and/or the nanostructures 203 continuously increases in a direction towards the substrate 100. In such embodiments, each of the nanostructures 203 may have a different width and be trapezoidal in shape.

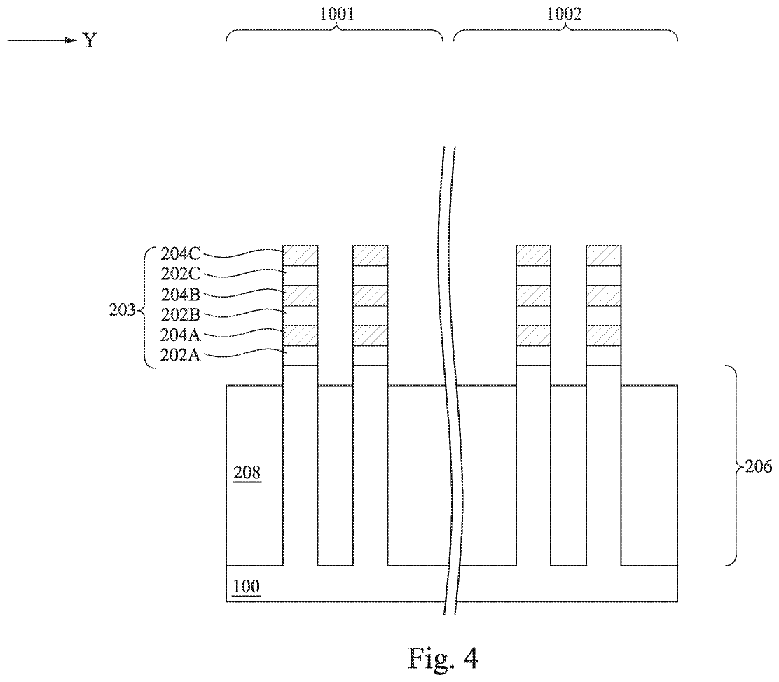

In FIG. 4, shallow trench isolation (STI) regions 208 are formed adjacent the fin structures 206. The STI regions 208 may be formed by depositing an insulation material over the substrate 100, the fin structures 206, and nanostructures 203, and between adjacent fin structures 206. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 203. Although the insulation material is illustrated as a single layer, some embodiments may utilize multiple layers. For example, in some embodiments a liner (not separately illustrated) may first be formed along a surface of the substrate 100, the fin structures 206, and the nanostructures 203. Thereafter, a fill material, such as those discussed above may be formed over the liner.

A removal process is then applied to the insulation material to remove excess insulation material over the nanostructures 203. In some embodiments, a planarization process such as a chemical mechanical polish (CMP), an etch-back process, combinations thereof, or the like may be utilized. The planarization process exposes the nanostructures 203 such that top surfaces of the nanostructures 203 and the insulation material are level after the planarization process is complete.

The insulation material is then recessed to form the STI regions 208. The insulation material is recessed such that upper portions of fin structures 206 in the first and second device regions 1001 and 1002 and protrude from between neighboring STI regions 208. Further, the top surfaces of the STI regions 208 may have a flat surface as illustrated, a convex surface, a concave surface (such as dishing), or a combination thereof. The top surfaces of the STI regions 208 may be formed flat, convex, and/or concave by an appropriate etch. The STI regions 208 may be recessed using an acceptable etching process, such as one that is selective to the material of the insulation material (e.g., etches the material of the insulation material at a faster rate than the material of the fin structures 206 and the nanostructures 203). For example, an oxide removal using, for example, dilute hydrofluoric (dHF) acid may be used.

The process described above with respect to FIGS. 2 through 4 is just one example of how the fin structures 206 and the nanostructures 203 may be formed. In some embodiments, the fin structures 206 and/or the nanostructures 203 may be formed using a mask and an epitaxial growth process. For example, a dielectric layer can be formed over a top surface of the substrate 100, and trenches can be etched through the dielectric layer to expose the underlying substrate 100. Epitaxial structures can be epitaxially grown in the trenches, and the dielectric layer can be recessed such that the epitaxial structures protrude from the dielectric layer to form the fin structures 206 and/or the nanostructures 203. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Additionally, the first semiconductor layers (and resulting nanostructures 202) and the second semiconductor layers (and resulting nanostructures 204) are illustrated and discussed herein as comprising the same materials in the second device region 1002 and the first device region 1001 for illustrative purposes only. As such, in some embodiments one or both of the first semiconductor layers and the second semiconductor layers may be different materials or formed in a different order in the first and second device regions 1001 and 1002.

Further in FIG. 4, appropriate wells (not separately illustrated) may be formed in the fin structures 206, the nanostructures 203, and/or the STI regions 208. In some embodiments with different well types in different device regions 1001 and 1002, different implant steps for the first device region 1001 and the second device region 1002 may be achieved using a photoresist or other masks (not separately illustrated). For example, a photoresist may be formed over the fin structures 206 and the STI regions 208 in the first device region 1001 and the second device region 1002. The photoresist is patterned to expose the second device region 1002. The photoresist can be formed by using a spin-on technique and can be patterned using acceptable photolithography techniques. Once the photoresist is patterned, a first impurity (e.g., n-type impurity such as phosphorus, arsenic, antimony, or the like) implant is performed in the second device region 1002, and the photoresist may act as a mask to substantially prevent the first impurities from being implanted into the first device region 1001. After the implant, the photoresist is removed, such as by an acceptable ashing process.

Following or prior to the implanting of the second device region 1002, a photoresist or other masks (not separately illustrated) is formed over the fin structures 206, the nanostructures 203, and the STI regions 208 in the first device region 1001 and the second device region 1002. The photoresist is then patterned to expose the first device region 1001. The photoresist can be formed by using a spin-on technique and can be patterned using acceptable photolithography techniques. Once the photoresist is patterned, a second impurity (e.g., p-type impurity such as boron, boron fluoride, indium, or the like) implant may be performed in the first device region 1001, and the photoresist may act as a mask to substantially prevent p-type impurities from being implanted into the second device region 1002. After the implant, the photoresist may be removed, such as by an acceptable ashing process.

After one or more well implants of the first device region 1001 and the second device region 1002, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

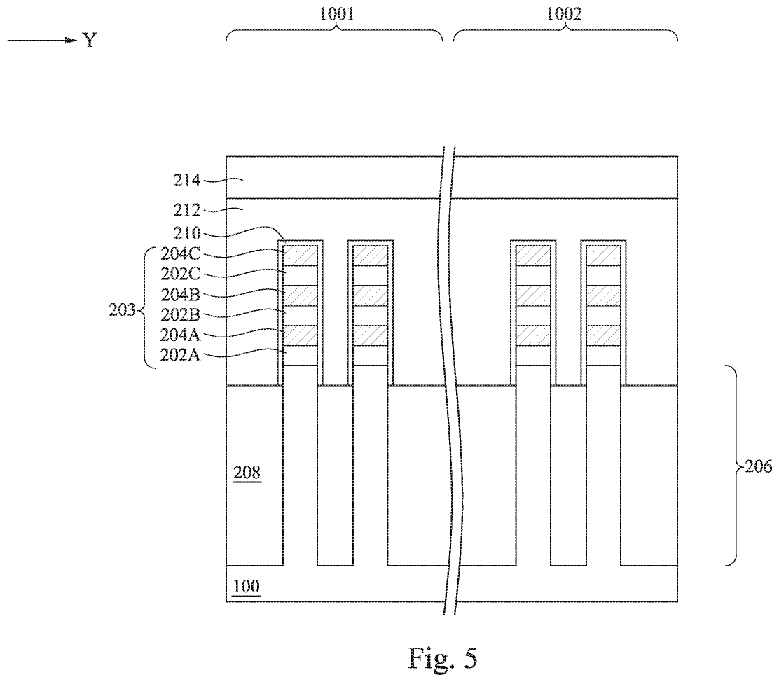

In FIG. 5, a dummy dielectric layer 210 is formed on the fin structures 206 and/or the nanostructures 203. The dummy dielectric layer 210 may be, for example, silicon oxide, silicon nitride, a combination thereof, or the like, and may be deposited or thermally grown according to acceptable techniques. A dummy gate layer 212 is formed over the dummy dielectric layer 210, and a mask layer 214 is formed over the dummy gate layer 212. The dummy gate layer 212 may be deposited over the dummy dielectric layer 210 and then planarized, such as by a CMP. The mask layer 214 may be deposited over the dummy gate layer 212. The dummy gate layer 212 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 212 may be deposited by physical vapor deposition (PVD), CVD, sputter deposition, or other techniques for depositing the selected material. The dummy gate layer 212 may be made of other materials that have a high etching selectivity from the etching of isolation regions. The mask layer 214 may include, for example, silicon nitride, silicon oxynitride, or the like. In this example, a single dummy gate layer 212 and a single mask layer 214 are formed across the first device region 1001 and the second device region 1002. It is noted that the dummy dielectric layer 210 is shown covering only the fin structures 206 and the nanostructures 203 for illustrative purposes only. In some embodiments, the dummy dielectric layer 210 may be deposited such that the dummy dielectric layer 210 covers the STI regions 208, such that the dummy dielectric layer 210 extends between the dummy gate layer 212 and the STI regions 208.

FIGS. 6A through 24 illustrate various following steps in the manufacturing of embodiment devices. FIGS. 6A, 7A, 8A, 9A, 10A, 11A, 12A, 13A, 13C, 14A, and 15A illustrate features in either the first device regions 1001 or the second device regions 1002. In FIGS. 6A and 6B, the mask layer 214 (see FIG. 5) may be patterned using acceptable photolithography and etching techniques to form masks 218. The pattern of the masks 218 then may be transferred to the dummy gate layer 212 and to the dummy dielectric layer 210 to form dummy gates 216 and dummy gate dielectrics 211, respectively. The dummy gates 216 cover respective channel regions of the fin structures 206. The pattern of the masks 218 may be used to physically separate each of the dummy gates 216 from adjacent dummy gates 216. The dummy gates 216 may also have a lengthwise direction substantially perpendicular to the lengthwise direction of respective fin structures 206.

In FIGS. 7A and 7B, a spacer layer 222 is formed over the structures illustrated in FIGS. 6A and 6B, respectively. The spacer layer 222 will be subsequently patterned to act as spacers for forming self-aligned source/drain regions. In FIGS. 7A and 7B, the spacer layer 222 is formed on top surfaces of the STI regions 208; top surfaces and sidewalls of the fin structures 206, the nanostructures 203, and the masks 218; and sidewalls of the dummy gates 216 and the dummy gate dielectric 211.

The spacer layer 222 is formed by atomic layer deposition (ALD), for example, thermal atomic layer deposition or plasma enhanced atomic layer deposition. FIGS. 7C and 7D illustrate a process 1000 of forming the spacer layer 222 in accordance with some embodiments. The process 1000 is performed to deposit the spacer layer 222 and includes atomic layer deposition (ALD) cycles 314 and an optional post treatment 316. In some embodiments, the spacer layer 222 is deposited using a furnace, a single wafer chamber, or a rotary apparatus at a temperature in a range from about 150° C. to about 650° C. By using the process 1000 to form the spacer layer 222, the spacer layer 222 can have a porous SiN based dielectric material with a step coverage of greater than about 95%. The spacer layer 222 can have a nitrogen atomic concentration in a range from about 0% to about 40%, and a density in a range from about 1.7 g/cm³ to about 2.4 g/cm³. In some embodiments, the spacer layer 222 has a dielectric constant in range from about 3.2 to about 5.2.

In FIG. 7D, some details for depositing the spacer layer 222 is illustrated, wherein some example intermediate chemical structures of the spacer layer 222 are illustrated. It is appreciated that the processes and structures as shown in (and discussed referring to) FIG. 7D are schematic, and other reaction mechanism and structures may also happen. Structures 304, 308, 312 are intermediate structures generated by different steps. A structure 209, which may represent the exposed features including the STI regions 208, the fin structure 206 and the nanostructures 203, is shown in FIG. 7D. In the illustrated example, the structure 209 is shown as including silicon, which may be in the form of silicon oxide, crystalline silicon, amorphous silicon, polysilicon, SiGe, or the like. In accordance with some embodiments of the present disclosure, due to the formation of native oxide and the exposure to moisture, Si—OH bonds (i.e., Si—OH dangling bonds) are formed at the surface of the structure 209. Two neighboring structures 209a and 209b are illustrated in FIG. 7D.

In some embodiments, the process 1000 begins with a step 302. In the step 302, a precursor P1 is introduced/pulsed into an ALD chamber, in which the substrate 100 (FIGS. 7A and 7B) is placed along with a carrier gas such as N₂, He, Ar, or a combination thereof. The precursor P1 is chemisorbed on the Si—OH dangling bonds. In some embodiment, the precursor P1 may include at least one Si atom. In some embodiments, the precursor P1 may include —CH₂— bond, and/or —CH₃— bond. The precursor P1 may include embedded Si—C—Si bonding to allow for a reduction in k-value of the spacer layer 222, which is beneficial for achieving further reduction in total capacitance. The strong Si—C—Si bonding can also provide the desired etch resistance, which can avoid device failure. By using the process 1000 to form the spacer layer 222, the spacer layer 222 can have a density of less than about 2.2 g/cm³ with a reduced amount of Si—CH₃ bonding.

In some embodiments, the precursor P1 may be a halogen precursor or an organic precursor. In some embodiments, the precursor P1 may include one or more chlorine atoms. The precursor P1 can be represented by Si(CH₂)SiRₐX_{b} Formula (a1). In the formula (a1), R may be H, Methyl (Me), Ethyl (Et), propyl (Pr), isopropyl (iPr), butyl (Bu), NMe2, NMeH, NH₂, NEt2, NiPrH, X may be Cl, Br, I, a≥0, b≥0, and a+b=6. An example of the precursor P1 may be represented by

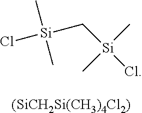

In some other embodiments, the precursor P1 can be represented by Si(CH₂)₂SiRₓCl_{y} Formula (a2). In the formula (a2), R may be H, Methyl (Me), Ethyl (Et), propyl (Pr), isopropyl (iPr), butyl (Bu), NMe2, NMeH, NH₂, NEt2, NiPrH, X may be Cl, Br, I, a≥0, b≥0, and a+b=4. An example of the precursor P1 may be represented by

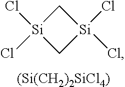

which is also named as tetrachloro-1,3-.disilacyclobutane (TCDSCB).

In some other embodiments, the precursor P1 can be represented by Si₃(CH₂)₃RₓCl_{y} Formula (a3). In the formula (a3), R may be H, Methyl (Me), Ethyl (Et), propyl (Pr), isopropyl (iPr), butyl (Bu), NMe2, NMeH, NH₂, NEt2, NiPrH, X may be Cl, Br, I, a≥0, b≥0, and a+b=6. An example of the precursor P1 may be represented by

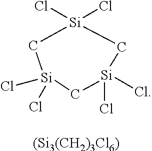

When the precursor P1 is pulsed into the ALD chamber, the substrate 100 may be heated, for example, to a temperature in a range between about 150° C. and about 650° C. The OH bonds as shown in the structure 300 (FIG. 7D) are broken, and oxygen atoms are bonded to silicon atoms of the precursor P1. Si—C—Si (with the C being in CH₂) bonds are formed to form a bridge structure connecting two Si—O bonds. The resulting structure is referred to as the structure 304. The structure 304 has chlorine as terminal groups.

After the step 302 has finished, the precursor P1 is purged from the ALD chamber by a purge gas such as argon, nitrogen, xenon, or other non-reactive gas to the ALD chamber. Next, further referring to FIGS. 7C and 7D, a step 306 is performed, and a bridging gas R1 is pulsed into the ALD chamber to form C—Si—N bonds (with the C being in CH₂). In some embodiments, the bridging gas R1 is ammonia (NH₃). An NH₄Cl molecule is generated in the step 306. With the introduction/pulsing of ammonia, the temperature of the substrate 100 is also kept elevated, for example, in the range from about 250° C. to about 400° C. to keep the desired Si—C—Si (with the C being in CH₂) bonds. FIG. 7H is some details for depositing the spacer layer 222 using ammonia as the bridging gas R1. Referring to FIG. 7H, if the temperature in the step 306 is higher than about 400° C., the Si—C—Si (with the C being in CH₂) bonds may be unwantedly broken, resulting a structure 305.

Referring back to FIGS. 7C and 7D, after the step 306 is finished, an oxygen-containing gas R2 is pulsed into the ALD chamber, to replace the N atom of the structure 308 with the O atom to form a terminal-OH group, resulting in the structure 312. The oxygen-containing gas R2 may be dissociated to form oxygen radicals using a suitable process, for example, using a plasma generation unit or remote plasma unit (not shown), and the structure 308 may react with the oxygen atoms, oxygen radicals. In some embodiments, after the step 310 is finished, the oxygen-containing gas R2 is purged from the ALD chamber by a purge gas such as argon, nitrogen, xenon, or other non-reactive gas to the ALD chamber.

In some embodiments, after a desired amount of the ALD cycles 314 is completed, the post treatment 316 is performed for residual gas removal and increase a desired amount of terminal-OH group of the structure 308. The post treatment 316 may increase a desired amount of terminal-OH group of the structure 308 to improve a quality of the spacer layer 222. In some embodiments, the post treatment 316 includes pulsing a treatment gas, such as, hydrogen, oxygen, ammonia, nitrogen gas, or a combination thereof, into the ALD chamber. The treatment gas may be dissociated to form active species including hydrogen radicals, oxygen radicals, ammonia radicals, or nitrogen radicals using a suitable process, for example, using a plasma generation unit or remote plasma unit (not shown), and the structure 312 may react with the hydrogen radicals, oxygen radicals, ammonia radicals, or nitrogen radicals.

In some embodiments, the post treatment 316 may be performed using thermal anneal, UV cure, or remote plasma treatment. In some embodiments, the post treatment 316 is thermal anneal which is performed by introducing He, Ar, N₂, a combination of N₂ and H₂, into the ALD chamber at a temperature in a range from about 350° C. to about 700° C. In other words, the post treatment 316 is performed at a He ambient gas, Ar ambient gas, N₂ ambient gas, or N₂ and H₂ ambient gas.

In some embodiments, the post treatment 316 is UV cure which is performed by introducing He, Ar, N₂ into the ALD chamber at a temperature in a range from about 150° C. to about 450° C. In other words, the post treatment 316 is performed at a He ambient gas, Ar ambient gas, or N₂ ambient gas.

In some embodiments, the post treatment 316 is remote plasma treatment which is performed by introducing He, H₂ N₂, or Ar into the ALD chamber at a temperature in a range from a room temperature to about 350° C.

FIGS. 7E, 7F and 7G illustrate a process 1000a of forming the spacer layer 222 in accordance with some embodiments. The process 1000a is performed to deposit the spacer layer 222 and includes atomic layer deposition (ALD) cycles 364 and an optional post treatment 366. In some embodiments, the spacer layer 222 is deposited using a furnace, a single wafer chamber, or a rotary apparatus at a temperature in a range from about 150° C. to about 650° C.

In FIGS. 7F and 7G, some details for depositing the spacer layer 222 is illustrated, wherein some example intermediate chemical structures of the spacer layer 222 are illustrated. It is appreciated that the processes and structures as shown in (and discussed referring to) FIGS. 7F and 7G are schematic, and other reaction mechanism and structures may also happen. Structures 352, 356, 358 and 362 are intermediate structures generated by different steps. The structure 209 is the same as the structure in FIG. 7D, and thus details of the description of the structure 209 are omitted herein.

The process 1000a begins with a step 350. The precursor P1 is introduced/pulsed into the ALD chamber, in which the substrate 100 (FIGS. 7A and 7B) is placed along with a carrier gas such as N₂, He, Ar, or a combination thereof. The step 350 is similar to the step 302 of the process 1000 as discussed previously with regard to FIG. 7D, and thus details of discussion thereof is omitted herein.

After the step 350 has finished, the precursor P1 is purged from the ALD chamber by a purge gas such as argon, nitrogen, xenon, or other non-reactive gas to the ALD chamber. Next, further referring to FIGS. 7E and 7F, a step 354 is performed, and a bridging gas R1 is pulsed into the ALD chamber to remove chlorine atoms from the structure 352, and HCl molecules may be generated. The structure 356 is thus formed. The structure 356 may turn into the structure 358 during the step 354. For example, one or more Si—H bonds are broken and the silicon atom in the Si—C—Si (with the C being in CH₂) bond may become a silicon radical. H₂ molecules are thus generated.

The structure 356 may then turn into the structure 360 during the step 354. For example, the two neighboring silicon radicals form a Si—Si bond, forming a bridge structure connecting two Si—O bonds. H₂ molecules are thus generated. After the step 354 is finished, an oxygen-containing gas R2 is pulsed into the ALD chamber to replace the H atom of the structure 360 with the OH group to form a terminal-OH group, resulting in the structure 362. The oxygen-containing gas R2 may be dissociated to form oxygen radicals using a suitable process, for example, using a plasma generation unit or remote plasma unit (not shown), and the structure 360 reacts with the oxygen atoms and/or the oxygen radicals. In some embodiments, after the step 354 is finished, the oxygen-containing gas R2 is purged from the ALD chamber by a purge gas such as argon, nitrogen, xenon, or other non-reactive gas to the ALD chamber.

In some embodiments, after a desired amount of the ALD cycles 364 is completed, the post treatment 366 is performed for residual gas removal and increase a desired amount of terminal-OH group of the structure 308. The post treatment 366 is similar to the post treatment 316 as discussed previously with regard to FIG. 7C, and thus the description thereof is omitted herein. Similarly, by using the process 1000a to form the spacer layer 222, the spacer layer 222 can have a porous SiN based dielectric material with a step coverage of greater than about 95%.

The bridging gas R1 can be ammonia or hydrogen as discussed with regard to FIGS. 7D and 7F, respectively. FIGS. 71 and 7J are some details for depositing the spacer layer 222 using oxygen as the bridging gas. A structure 307 is an example intermediate chemical structure of the spacer layer 222. When the bridging gas R1 is oxygen, the Si—C—Si (with the C being in CH₂) bond would be disadvantageously broken by the oxygen radicals generated from the oxygen, and a catalyst is required to form the Si—C—Si (with the C being in CH₂) bonds again to form a desired structure 309.

FIGS. 7K, 7L and 7M illustrate a process 1000b of forming the spacer layer 222 in accordance with some embodiments. The process 1000b is performed to deposit the spacer layer 222 and includes atomic layer deposition (ALD) cycles 314b and an optional post treatment 316. The process 1000b is similar to the process 1000 as discussed previously with regard to FIGS. 7C and 7D, except for the process 1000b further comprising a step 368 and a step 372. The step 368 is configured to activate the surface of the structure 304. In the process 1000b, after performing the step 302 and the precursor P1 is purged from the ALD chamber, the step 368 is performed using a reactant gas A1. The reactant gas A1 is pulsed into the ALD chamber to remove the chlorine atoms from the structure 304, and HCl molecules may be generated. The structure 370 is thus formed. In some embodiments, the reactant gas A1 is hydrogen gas, and the step 368 is a microwave plasma process carried out using the hydrogen gas (H₂).

In some embodiments, after the step 306 is performed, the step 372 is performed. The step 372 is configured to activate the surface of the structure 308b. In the step 372, a reactant gas A2 is pulsed into the ALD chamber. In some embodiments, the reactant gas A2 is hydrogen gas, and the step 372 is a microwave plasma process carried out using the hydrogen gas (H₂). After the step 372 is performed, the oxygen-containing gas R2 is pulsed into the ALD chamber, to replace the N atom of the structure 308 with the O atom to form the terminal-OH group, resulting in the structure 312b.

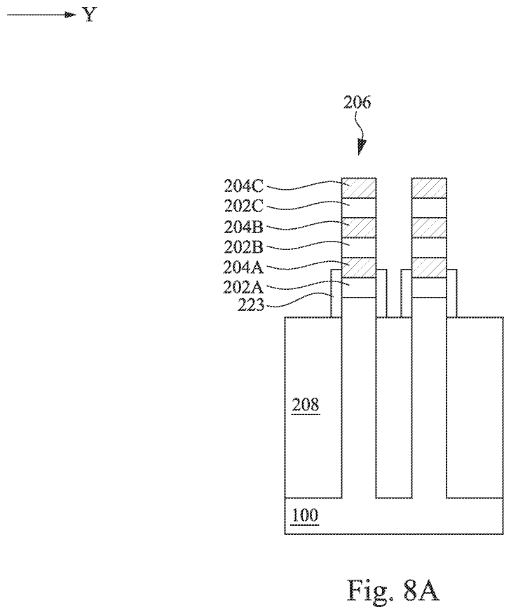

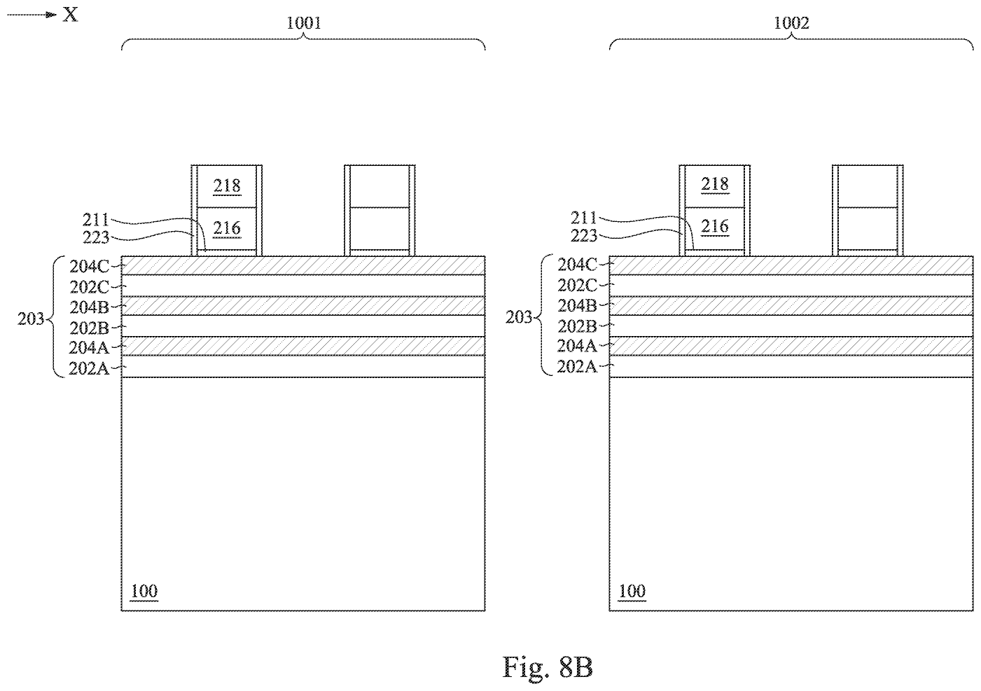

In FIGS. 8A and 8B, the spacer layer 220 is etched to form spacers 223. As will be discussed in greater detail below, the spacers 223 act to self-align subsequently formed source drain regions, as well as to protect sidewalls of the fin structures 206 and/or nanostructure 203 during subsequent processing. The spacer layer 222 may be etched using a suitable etching process, such as an isotropic etching process (e.g., a wet etching process), an anisotropic etching process (e.g., a dry etching process), or the like.

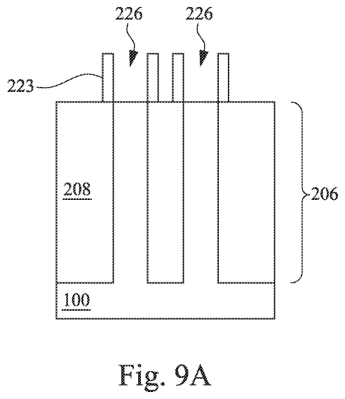

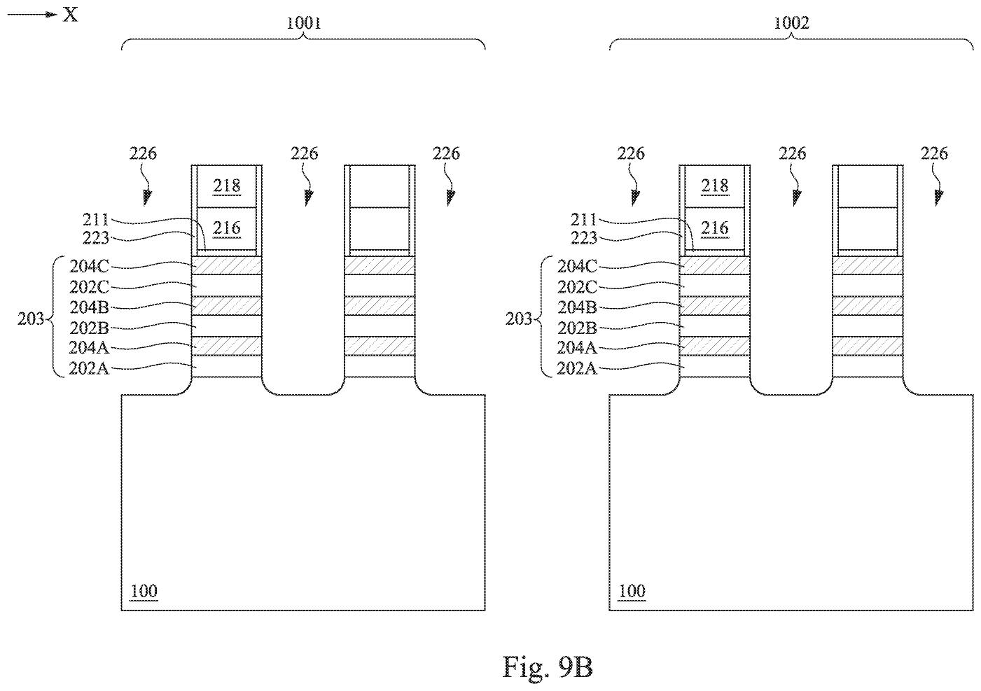

In FIGS. 9A and 9B, source/drain recesses 226 are formed in the fin structures 206, the nanostructures 203, and the substrate 100, in accordance with some embodiments. Epitaxial source/drain regions will be subsequently formed in the source/drain recesses 226. The source/drain recesses 226 may extend through the first nanostructures 202 and the second nanostructures 204, and into the substrate 100. As illustrated in FIG. 9A, bottom surfaces of the source/drain recesses 226 may be level with top surfaces of the STI regions 58, as an example. In some other embodiments, the fin structures 206 may be etched such that bottom surfaces of the source/drain recesses 226 are disposed below the top surfaces of the STI regions 208, or above the top surfaces of the STI regions 208. The source/drain recesses 226 may be formed by etching the fin structures 206, the nanostructures 203, and the substrate 100 using anisotropic etching processes, such as RIE, NBE, or the like. The spacers 223 and the masks 218 mask portions of the fin structures 206, the nanostructures 203, and the substrate 100 during the etching processes used to form the source/drain recesses 226. A single etch process or multiple etch processes may be used to etch each layer of the nanostructures 203 and/or the fin structures 206. Timed etch processes may be used to stop the etching of the source/drain recesses 226 after the source/drain recesses 226 reach a target depth.

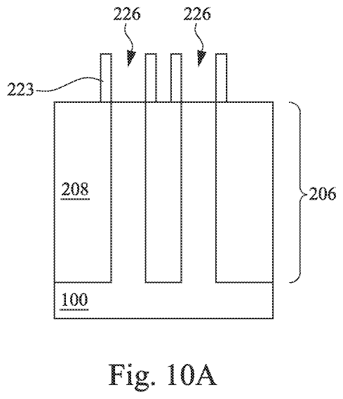

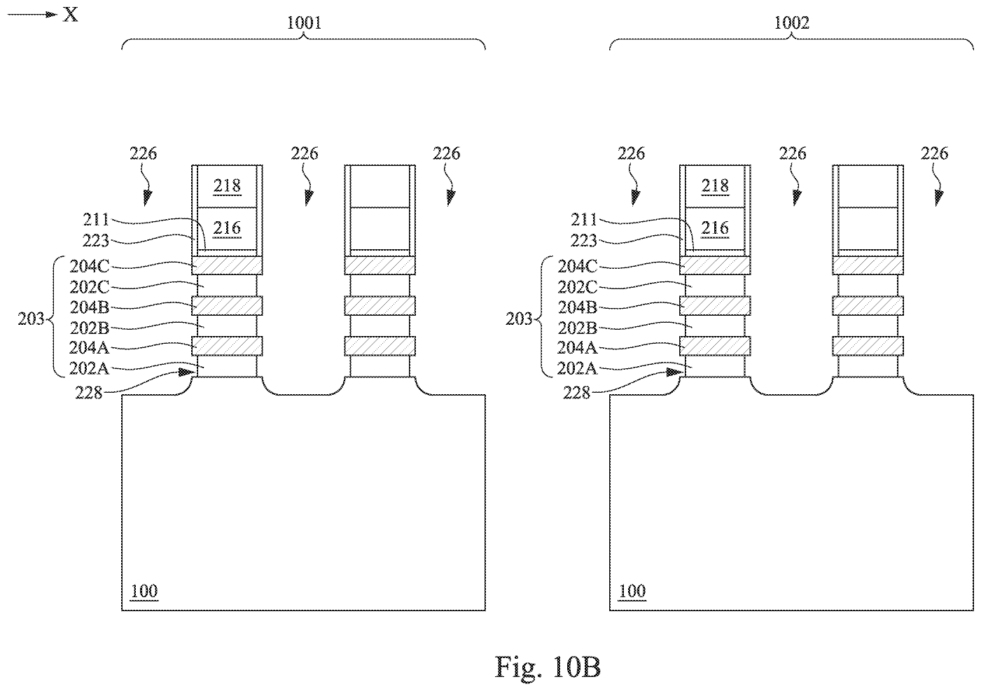

In FIGS. 10A and 10B, portions of sidewalls of the layers of the multi-layer stack 201 formed of the first semiconductor materials (e.g., the first nanostructures 202) exposed by the source/drain recesses 226 are etched to form sidewall recesses 228 between corresponding second nanostructures 204. Although sidewalls of the first nanostructures 202 in the sidewall recesses 228 are illustrated as being straight in FIG. 10B, the sidewalls may be concave or convex. The sidewalls may be etched using isotropic etching processes, such as wet etching or the like. In some embodiments in which the first nanostructures 202 include, e.g., SiGe, and the second nanostructures 204 include, e.g., Si or SiC, a dry etch process with tetramethylammonium hydroxide (TMAH), ammonium hydroxide (NH₄OH), or the like may be used to etch sidewalls of the first nanostructures 202.

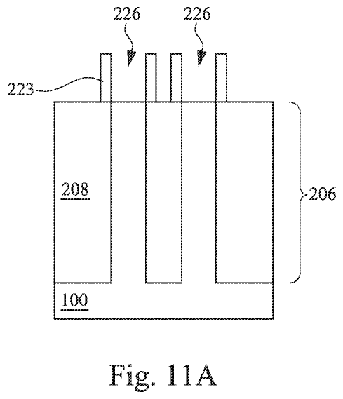

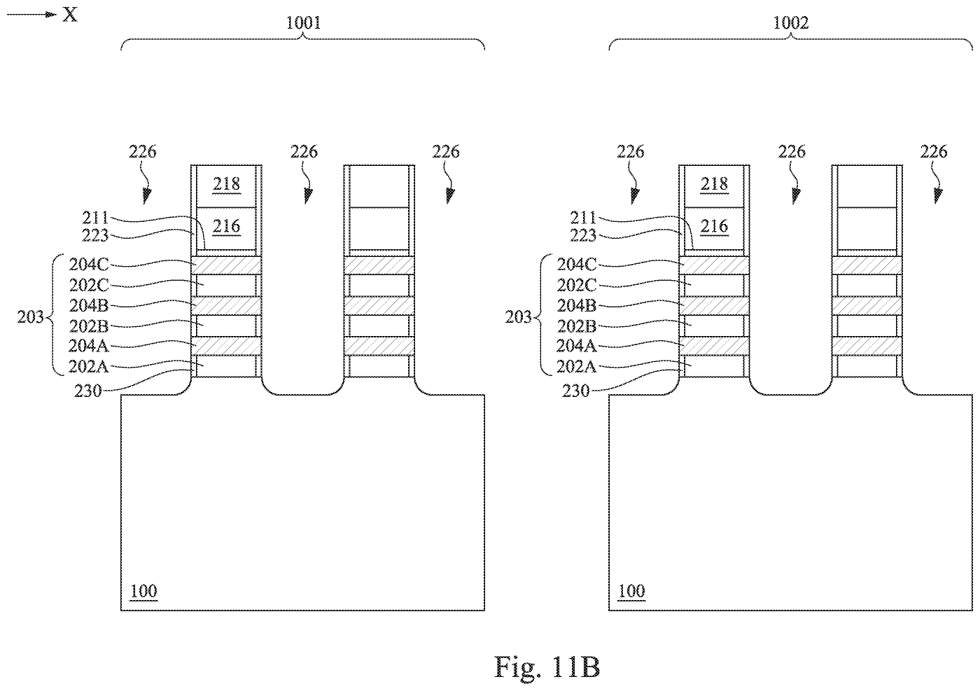

In FIGS. 11A-11B, inner spacers 230 are formed in the sidewall recess 228. The inner spacers 230 may be formed by depositing an inner spacer layer (not separately illustrated) over the structures illustrated in FIGS. 10A and 10B using the process 1000 as discussed with regard to FIGS. 7C and 7D or the process 1000a as discussed with regard to FIGS. 7F-7H, and thus the details of description thereof is omitted herein. The inner spacer layer may then be anisotropically etched to form the inner spacers 230, such as RIE, NBE, or the like. By using the processes 1000 or 1000a to form the inner spacer layer, the inner spacers 230 can have a porous SiN based dielectric material with a step coverage of greater than about 95%. The inner spacers 230 can have a nitrogen atomic concentration in a range from about 0% to about 40%, and a density in a range from about 1.7 g/cm³ to about 2.4 g/cm³. In some embodiments, the inner spacers 230 have a dielectric constant in range from about 3.2 to about 5.2.

The inner spacers 230 act as isolation features between subsequently formed source/drain regions and gate structure. As will be discussed in greater detail below, source/drain regions will be formed in the source/drain recesses 226, and the first nanostructures 202 will be replaced with corresponding gate structures. Although outer sidewalls of the inner spacers 230 are illustrated as being flush with sidewalls of the second nanostructures 204, the outer sidewalls of the inner spacers 230 may extend beyond or be recessed from sidewalls of the second nanostructures 204.

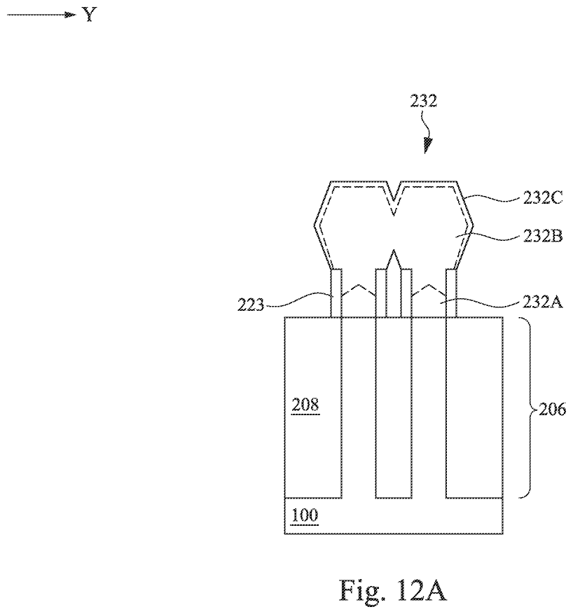

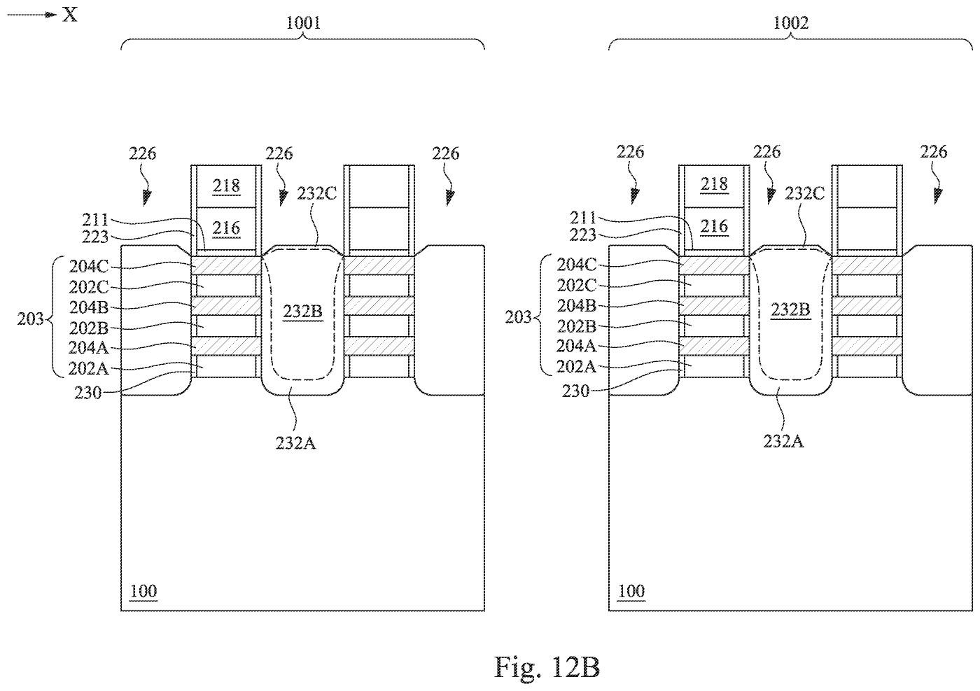

Moreover, although the outer sidewalls of the inner spacers 230 are illustrated as being straight in FIG. 11B, the outer sidewalls of the inner spacers 230 may be concave or convex. The inner spacers 230 may be used to prevent damage to subsequently formed source/drain regions (such as the epitaxial source/drain regions 232, discussed below with respect to FIGS. 12A-12B) by subsequent etching processes, such as etching processes used to form gate structures.

In FIGS. 12A-12B, epitaxial source/drain regions 232 are formed in the source/drain recesses 226. In some embodiments, the epitaxial source/drain regions 232 may exert stress on the second nanostructures 204, thereby improving device performance. As illustrated in FIG. 12B, the epitaxial source/drain regions 232 are formed in the source/drain recesses 226 such that each dummy gate 216 is disposed between respective neighboring pairs of the epitaxial source/drain regions 232. In some embodiments, the spacers 223 are used to separate the epitaxial source/drain regions 232 from the dummy gates 216 and the inner spacers 230 are used to separate the epitaxial source/drain regions 232 from the first nanostructures 202 by an appropriate lateral distance so that the epitaxial source/drain regions 232 do not short out with subsequently formed gates of the resulting GAA-FETs.

In some embodiments, the epitaxial source/drain regions 232 may include any acceptable material appropriate for n-type GAA-FETs. For example, if the second nanostructures 204 are silicon, the epitaxial source/drain regions 232 may include materials exerting a tensile strain on the second nanostructures 204, such as silicon carbide, phosphorous doped silicon carbide, silicon phosphide, or the like. In some embodiments, the epitaxial source/drain regions 232 may include any acceptable material appropriate for p-type GAA-FETs. For example, if the second nanostructures 204 are silicon, the epitaxial source/drain regions 232 may comprise materials exerting a compressive strain on the second nanostructures 204, such as silicon germanium, boron doped silicon germanium, germanium, germanium tin, or the like. The epitaxial source/drain regions 232 may have surfaces raised from respective upper surfaces of the nanostructures 203 and may have facets.

The epitaxial source/drain regions 232 may be implanted with dopants to form source/drain regions, followed by an anneal. The n-type and/or p-type impurities for source/drain regions may be any of the impurities previously discussed. In some embodiments, the epitaxial source/drain regions 232 may be in situ doped during growth.

As a result of the epitaxy processes used to form the epitaxial source/drain regions 232, upper surfaces of the epitaxial source/drain regions 232 have facets which expand laterally outward beyond sidewalls of the nanostructures 203. In some embodiments, these facets cause adjacent epitaxial source/drain regions 232 to merge as illustrated by FIG. 12A. In some other embodiments, adjacent epitaxial source/drain regions 232 remain separated after the epitaxy process is completed. In the embodiments illustrated in FIG. 12A, the spacers 223 may be formed to a top surface of the STI regions 208 thereby blocking the lateral epitaxial growth. In some other embodiments, the spacers 223 may cover portions of the sidewalls of the nanostructures 203 further blocking the epitaxial growth. In some other embodiments, the spacer etch used to form the spacers 223 may be adjusted to remove the spacer material to allow the epitaxially grown region to extend to the surface of the STI region 58.

The epitaxial source/drain regions 232 may comprise one or more semiconductor material layers. For example, the epitaxial source/drain regions 232 may comprise a first semiconductor material layer 232A, a second semiconductor material layer 232B, and a third semiconductor material layer 232C. Any number of semiconductor material layers may be used for the epitaxial source/drain regions 232. Each of the first semiconductor material layer 232A, the second semiconductor material layer 232B, and the third semiconductor material layer 232C may be formed of different semiconductor materials and may be doped to different dopant concentrations. In some embodiments, the first semiconductor material layer 232A may have a dopant concentration less than the second semiconductor material layer 232B and greater than the third semiconductor material layer 232C. In embodiments in which the epitaxial source/drain regions 232 comprise three semiconductor material layers, the first semiconductor material layer 232A may be deposited, the second semiconductor material layer 232B may be deposited over the first semiconductor material layer 232A, and the third semiconductor material layer 232C may be deposited over the second semiconductor material layer 232B.

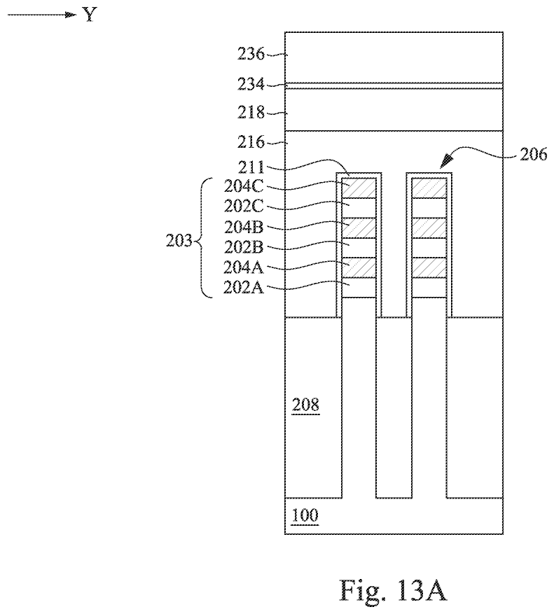

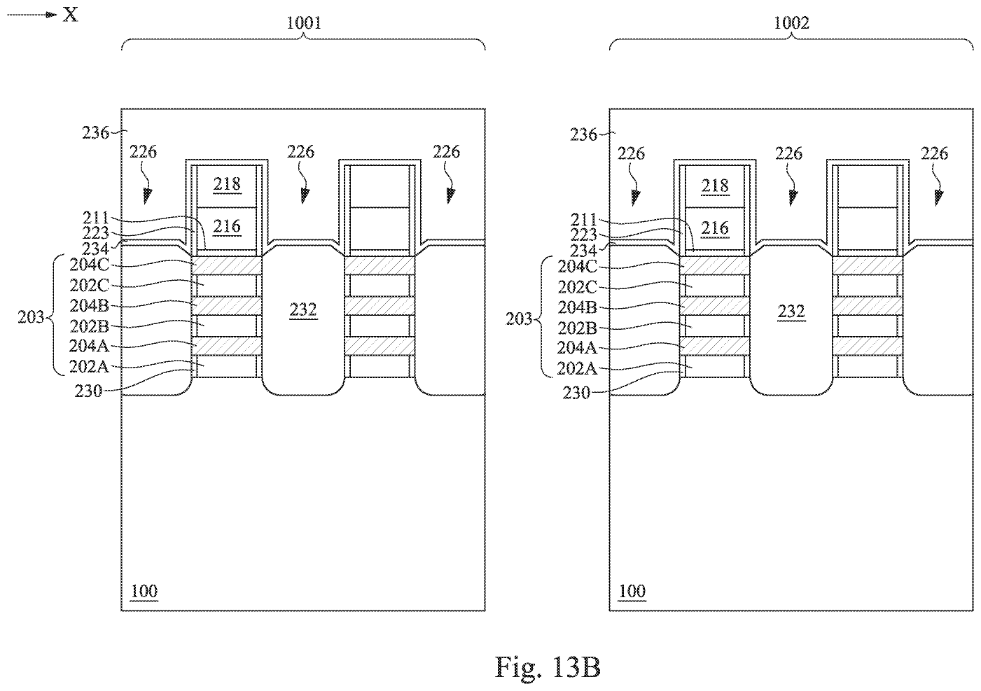

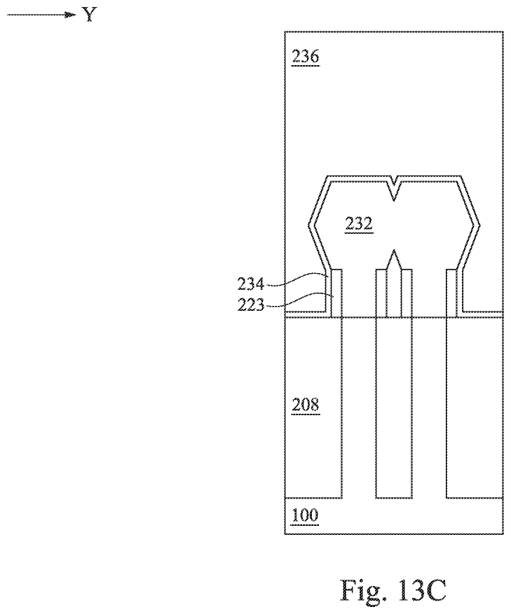

In FIGS. 13A-13C, an interlayer dielectric (ILD) layer 236 is deposited over the structure illustrated in FIGS. 12A-12B. The ILD layer 236 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 234 is disposed between the ILD layer 236 and the epitaxial source/drain regions 232, the masks 218, and the spacers 223. The CESL 234 may comprise a dielectric material, such as, silicon nitride, silicon oxide, silicon oxynitride, or the like, having a different etch rate than the material of the overlying ILD layer 236.

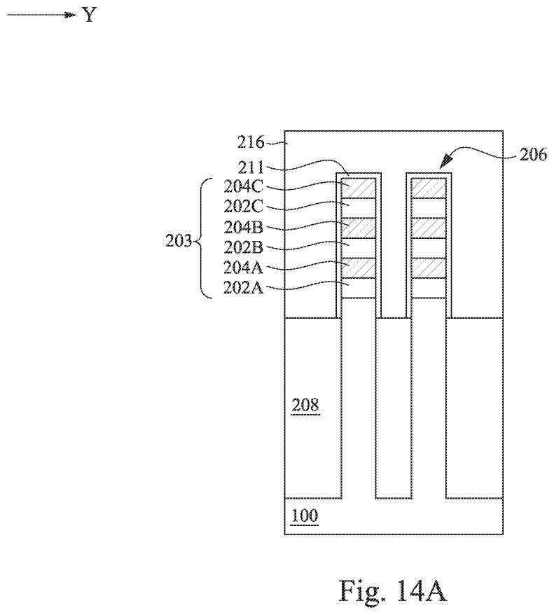

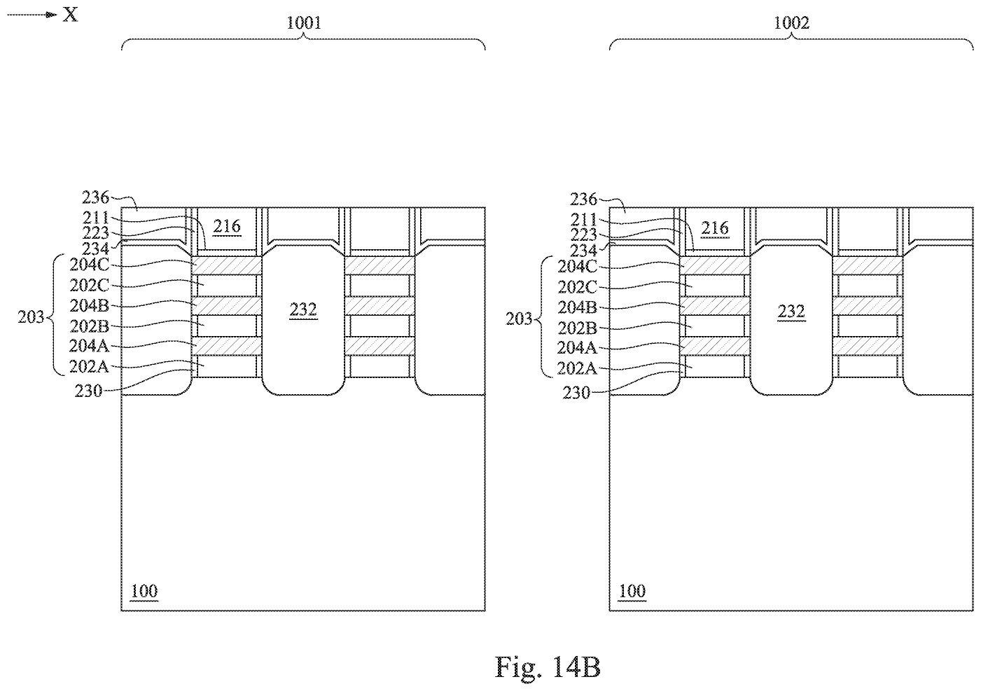

In FIGS. 14A-14B, a planarization process, such as a CMP, may be performed to level the top surface of the ILD layer 236 with the top surfaces of the dummy gates 216 or the masks 218. The planarization process may also remove the masks 218 on the dummy gates 216, and portions of the spacers 223 along sidewalls of the masks 218. After the planarization process, top surfaces of the dummy gates 216, the spacers 223, and the ILD layer 236 are level within process variations. Accordingly, the top surfaces of the dummy gates 216 are exposed through the ILD layer 236. In some embodiments, the masks 218 may remain, in which case the planarization process levels the top surface of the ILD layer 236 with top surface of the masks 218 and the spacers 223.

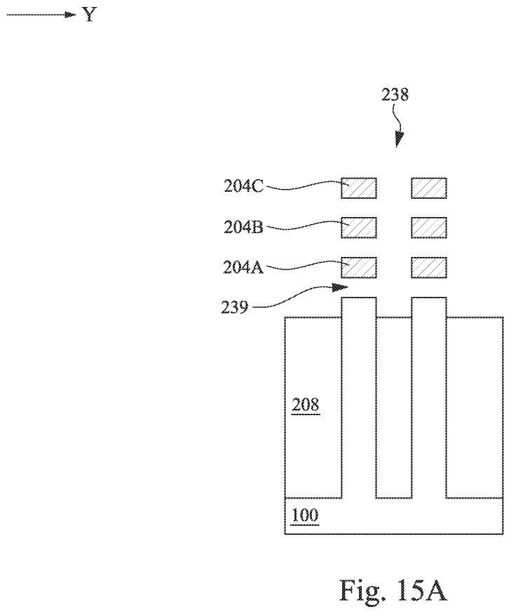

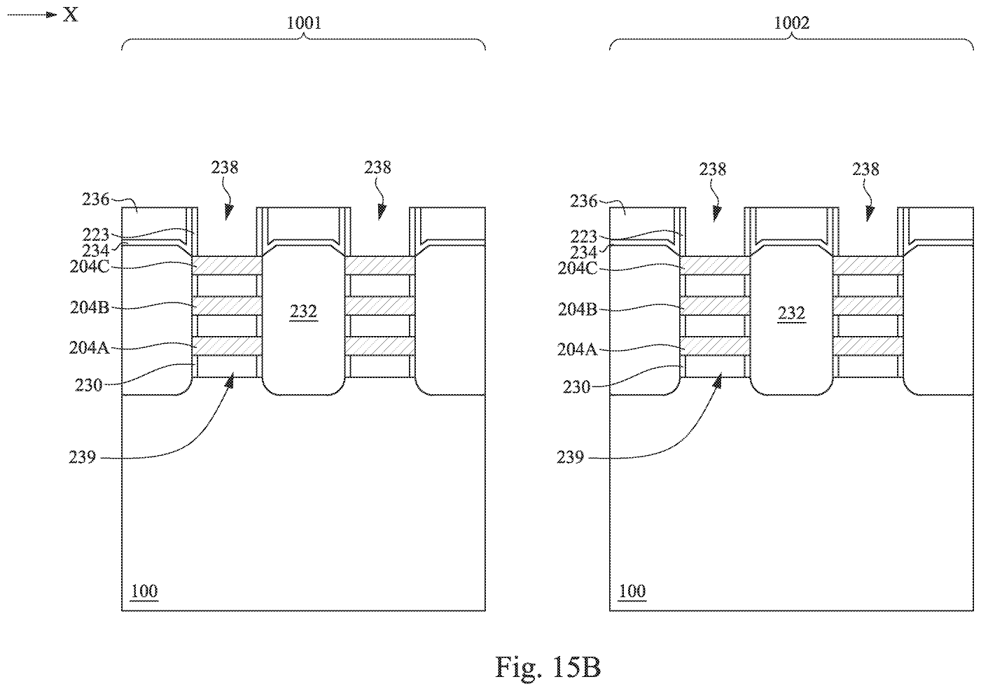

In FIGS. 15A and 15B, the dummy gates 216, and the masks 218 if present, are removed in one or more etching steps, so that gate trenches 238 are formed between corresponding spacers 221. In some embodiments, portions of the dummy gate dielectrics 211 in the gate trenches 238 are also be removed. In some embodiments, the dummy gates 216 and the dummy gate dielectrics 211 are removed by an anisotropic dry etch process. For example, the etching process may include a dry etch process using reaction gas(es) that selectively etch the dummy gates 216 at a faster rate than the ILD layer 236 or the spacers 221. Each gate trench 238 exposes and/or overlies portions of nanostructures 204, which act as channel regions in subsequently completed GAA-FETs. The nanostructures 204 which act as the channel regions are disposed between neighboring pairs of the epitaxial source/drain regions 232. During the removal, the dummy gate dielectrics 211 may be used as etch stop layers when the dummy gates 216 are etched. The dummy gate dielectrics 211 may then be removed after the removal of the dummy gates 216.

In FIGS. 15A and 15B, the first nanostructures 202 in the gate trenches 238 are removed by an isotropic etching process such as wet etching or the like using etchants which are selective to the materials of the first nanostructures 202. Stated differently, the first nanostructures 202 are removed by using a selective etching process that etches the first nanostructures 202 at a faster etch rate than it etches the second nanostructures 204, thus forming spaces between the second nanostructures 204 (also referred to as sheet-sheet spaces if the nanostructures 204 are nanosheets). This step can be referred to as a channel release process. As illustrated in FIGS. 15A and 15B, gaps 239 (empty spaces) are formed between the second nanostructures 204. At this interim processing step, the gaps 239 between second nanostructures 204 may be filled with ambient environment conditions (e.g., air, nitrogen, etc). In some embodiments, the second nanostructures 204 can be referred to as nanosheets, nanowires, nanoslabs, nanorings having nano-scale size (e.g., a few nanometers), depending on their geometry. For example, in some embodiments, the second nanostructures 204 may be trimmed to have a substantial rounded shape (i.e., cylindrical) due to the selective etching process for completely removing the first nanostructures 202. In that case, the resultant second nanostructures 204 can be called nanowires.

In embodiments in which the first nanostructures 202 include, e.g., SiGe, and the second nanostructures 204 include, e.g., Si or SiC, tetramethylammonium hydroxide (TMAH), ammonium hydroxide (NH₄OH) or the like may be used to remove the first nanostructures 202. In some embodiments, both the channel release step and the previous step of laterally recessing first nanostructures 202 (i.e., the step as illustrated in FIG. 10B) use a selective etching process that etches first nanostructures 202 (e.g., SiGe) at a faster etch rate than etching second nanostructures 204 (e.g., Si), and therefore these two steps may use the same etchant chemistry in some embodiments. In this case, the etching time/duration of channel release step is longer than the etching time/duration of the previous step of laterally recessing first nanostructures 202, so as to completely remove the sacrificial nanostructures 202.

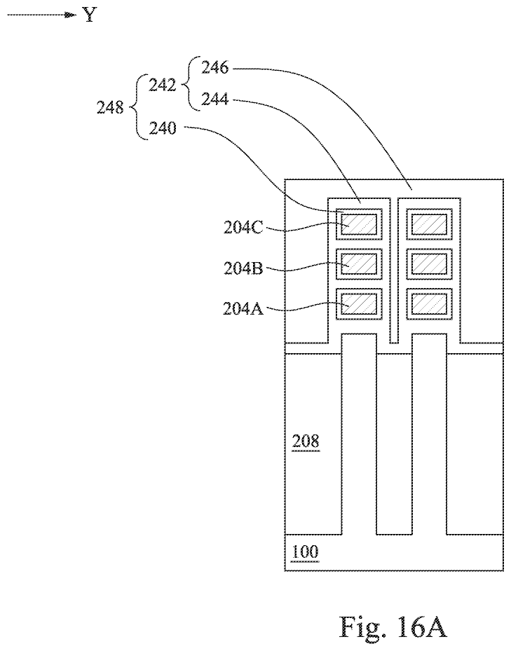

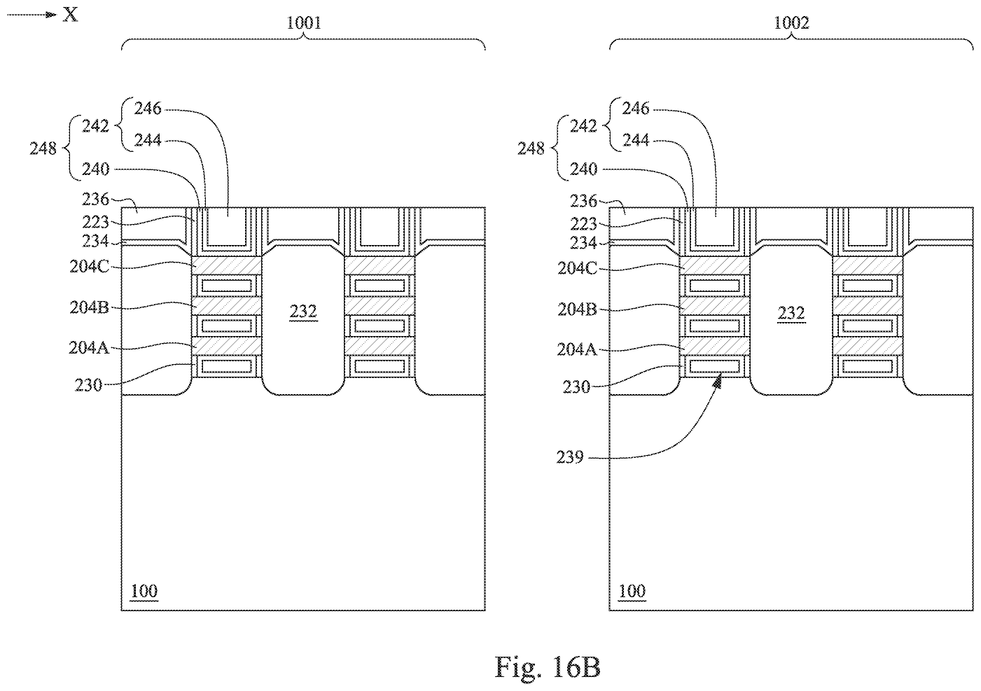

Next, in FIGS. 16A and 16B, high-k/metal gate structures are formed. For example, a gate dielectric layer 240 is formed (e.g., conformally) in the gate trenches 238 and in the gaps 239. The gate dielectric layer 240 wraps around the second nanostructures 204, lines sidewalls of the inner spacers 230 and sidewalls of the spacers 223, and extends along the upper surface of the fin structures 206. In accordance with some embodiments, the gate dielectric layer 120 comprises silicon oxide, silicon nitride, or multilayers thereof. In some embodiments, the gate dielectric layer 240 includes a high-k dielectric material, and in these embodiments, the gate dielectric layer 240 may have a dielectric constant greater than about 7.0, and may include a metal oxide or a silicate of Hf, Al, Zr, La, Mg, Ba, Ti, or Pb, or combinations thereof. The formation methods of the gate dielectric layer 240 may include Molecular-Beam Deposition (MBD), ALD, PECVD, and the like.

In an alternative embodiment, an interfacial layer (not shown) is deposited between the gate dielectric layer 240 and the second nanostructures 204 and is formed of silicon oxide or silicon oxynitride grown by a thermal oxidation process. For example, the interfacial layer can be grown by a rapid thermal oxidation (RTO) process or by an annealing process using oxygen.

Next, a gate electrode material (e.g., an electrically conductive material) is formed in the gate trenches 238 and in the gaps 239 to form the gate electrodes 242. The gate electrodes 242 fill the remaining portions of the gate trenches 238 and in the gaps 239. For example, the gate electrodes 242 include one or more work function layers 244 and a fill metal layer 246. A CMP is then performed on the fill metal layer 246, the one or more work function layers 244 and the gate dielectric layer 240 until the ILD layer 236 is exposed, resulting in the fill metal layer 246, the one or more work function layers 244 and the gate dielectric layer 240, the CESL 234, and the ILD layer 236 having substantially level top surfaces. The gate electrodes 242 and the gate dielectric layer 240 are collectively referred to as metal gate structures 248.

The one or more work function layers 244 may be deposited to surround each of the second nanostructures 204. A portion of the one or more work function layers 244 is formed vertically between adjacent second nanostructures 204 and fills the gaps 239 between adjacent second nanostructures 204.

The one or more work function layers 244 can provide a suitable work function for the high-k/metal gate structures. For an n-type GAA FET, the one or more work function layers 244 may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AIC)), aluminides, and/or other suitable materials. On the other hand, for a p-type GAA FET, the one or more work function layers 244 may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials.

In some embodiments, the fill metal layer 246 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

Based on the above discussions, it can be seen that the present disclosure in various embodiments offers advantages. It is understood, however, that other embodiments may offer additional advantages, and not all advantages are necessarily disclosed herein, and that no particular advantage is required for all embodiments. One advantage is that by using a precursor with embedded Si—C—Si bonding to combine benefits of low k-value and Si—C—Si bonding, the precursor allows for a reduction in k-value of an as-deposited spacer layer while the Si—C—Si bonding provides desired resistance to etch processes. Another advantage is that low capacitance value without sacrificing etch resistivity can be achieved.

In some embodiments, a method of forming a semiconductor device comprises the following steps. A fin is formed protruding from a substrate. A dummy gate is formed across the fin. Gate spacers are formed on opposite sidewalls of the dummy gate using one or more atomic layer deposition (ALD) cycles. Each of the ALD cycles comprises pulsing a precursor to the dummy gate, after pulsing the precursor to the dummy gate, pulsing a bridging gas to the dummy gate, wherein the bridging gas is ammonia, hydrogen, or a combination thereof, and after pulsing the bridging gas to the dummy gate, pulsing an oxygen-containing gas to the dummy gate. The dummy gate is replaced with a metal gate. In some embodiments, the precursor is represented by:

Si(CH₂)SiRₐX_{b} Formula (a1), and wherein in the formula (a1), R is H, Methyl (Me), Ethyl (Et), propyl (Pr), isopropyl (iPr), butyl (Bu), NMe2, NMeH, NH₂, NEt2, or NiPrH, X is Cl, Br, or I, a≥0, b≥0, and a+b=6. In some embodiments, the precursor is represented by

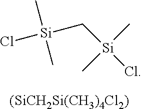

In some embodiments, the precursor is represented by:

Si(CH₂)₂SiRₓCl_{y} Formula (a2), and wherein in the formula (a2), R is H, Methyl (Me), Ethyl (Et), propyl (Pr), isopropyl (iPr), butyl (Bu), NMe2, NMeH, NH₂, NEt2, or NiPrH, X is Cl, Br, or I, a≥0, b≥0, and a+b=4. In some embodiments, the precursor is represented by

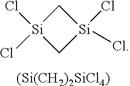

In some embodiments, the precursor is represented by:

Si₃(CH₂)₃RₓCl_{y} Formula (a3), and wherein in the formula (a3), R is H, Methyl (Me), Ethyl (Et), propyl (Pr), isopropyl (iPr), butyl (Bu), NMe2, NMeH, NH₂, NEt2, or NiPrH, X is Cl, Br, or I, a≥0, b≥0, and a+b=6. In some embodiments, the precursor is represented by

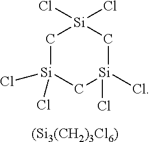

In some embodiments, each of the ALD cycles further comprises prior to pulsing the precursor to the dummy gate, pulsing a hydrogen gas to the dummy gate. In some embodiments, each of the ALD cycles further comprises after pulsing the precursor to the dummy gate, pulsing a hydrogen gas to the dummy gate. In some embodiments, the method further comprises after forming the gate spacers on the opposite sidewalls of the dummy gate, performing a post treatment to the gate spacers using a thermal anneal, a UV cure or a remote plasma treatment.

In some embodiments, a method of forming a semiconductor device comprises the following steps. A fin is formed protruding from a substrate, wherein the fin comprises alternately stacked first semiconductor layers and second semiconductor layers. Sidewalls of the first semiconductor layers are etched to form sidewall recesses between corresponding second semiconductor layers. Inner spacers are formed in the sidewall recesses using one or more atomic layer deposition (ALD) cycles. Each of the ALD cycles comprises pulsing a precursor to the sidewall recesses. The precursor comprises at least one Si atom, at least one halogen atom, and —CH₂— bond or —CH₃— bond. Epitaxial source/drain regions are formed on opposite sides of the fin. The first semiconductor layers are removed to form spaces each between the second semiconductor layers. A metal gate is formed wrapping around each of the second semiconductor layers. In some embodiments, the precursor is represented by:

Si(CH₂)SiRₐX_{b} Formula (a1), and wherein in the formula (a1), R is H, Methyl (Me), Ethyl (Et), propyl (Pr), isopropyl (iPr), butyl (Bu), NMe2, NMeH, NH₂, NEt2, or NiPrH, X is Cl, Br, or I, a≥0, b≥0, and a+b=6. In some embodiments, the precursor is represented by

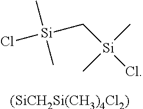

In some embodiments, the precursor is represented by:

Si(CH₂)₂SiRₓCl_{y} Formula (a2), and wherein in the formula (a2), R is H, Methyl (Me), Ethyl (Et), propyl (Pr), isopropyl (iPr), butyl (Bu), NMe2, NMeH, NH₂, NEt2, or NiPrH, X is Cl, Br, or I, a≥0, b≥0, and a+b=4. In some embodiments, the precursor is represented by

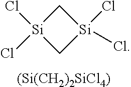

In some embodiments, the precursor is represented by: Si₃(CH₂)₃RₓCl_{y} Formula (a3), and wherein in the formula (a3), R is H, Methyl (Me), Ethyl (Et), propyl (Pr), isopropyl (iPr), butyl (Bu), NMe2, NMeH, NH₂, NEt2, or NiPrH, X is Cl, Br, I, a≥0, b≥0, and a+b=6. In some embodiments, the precursor is represented by

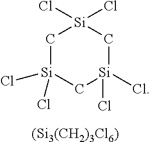

In some embodiments, pulsing the precursor to the sidewall recesses comprises pulsing the precursor at a temperature in a range from about 250° C. to about 400° C.

In some embodiments, a semiconductor device comprises a substrate, a nanostructure protruding from the substrate, a gate structure across the nanostructure and gate spacers extending along opposite sidewalls of the gate structure. The nanostructure has a surface comprising Si—O bonds. The gate spacers comprise a dielectric constant in a range from about 3.2 to about 5.2, and the gate spacers comprise Si—C—Si bonds to form a bridge structure connecting two neighboring Si—O bonds, and wherein C in the Si—C—Si bonds of the gate spacers is CH₂. In some embodiments, the semiconductor device further comprises epitaxial source/drain regions on opposite sides of the gate structure and inner spacers laterally between the gate structure and the epitaxial source/drain regions, wherein the inner spacers comprise Si—C—Si bonds to form a bridge structure connecting two neighboring Si—O bonds, and wherein C in the Si—C—Si bonds of the inner spacers is CH₂.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, comprising:
forming a fin protruding from a substrate;
forming a dummy gate across the fin;
forming gate spacers on opposite sidewalls of the dummy gate using one or more atomic layer deposition (ALD) cycles, wherein each of the ALD cycles comprises:
pulsing a precursor to the dummy gate;
after pulsing the precursor to the dummy gate, pulsing a bridging gas to the dummy gate, wherein the bridging gas is ammonia, hydrogen, or a combination thereof; and
after pulsing the bridging gas to the dummy gate, pulsing an oxygen-containing gas to the dummy gate; and
replacing the dummy gate with a metal gate.

2. The method of claim 1, wherein the precursor is represented by:
Si(CH₂)SiRₐX_{b} Formula (a1), and wherein in the formula (a1), R is H, Methyl (Me), Ethyl (Et), propyl (Pr), isopropyl (iPr), butyl (Bu), NMe2, NMeH, NH₂, NEt2, or NiPrH, X is Cl, Br, or I, a≥0, b≥0, and a+b=6.

3. The method of claim 1, wherein the precursor is represented by

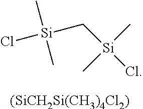

4. The method of claim 1, wherein the precursor is represented by:
Si(CH₂)₂SiRₓCl_{y} Formula (a2), and wherein in the formula (a2), R is H, Methyl (Me), Ethyl (Et), propyl (Pr), isopropyl (iPr), butyl (Bu), NMe2, NMeH, NH₂, NEt2, or NiPrH, X is Cl, Br, or I, a≥0, b≥0, and a+b=4.

5. The method of claim 1, wherein the precursor is represented by

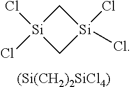

6. The method of claim 1, wherein the precursor is represented by:
Si₃(CH₂)₃RₓCl_{y} Formula (a3), and wherein in the formula (a3), R is H, Methyl (Me), Ethyl (Et), propyl (Pr), isopropyl (iPr), butyl (Bu), NMe2, NMeH, NH₂, NEt2, or NiPrH, X is Cl, Br, or I, a≥0, b≥0, and a+b=6.

7. The method of claim 1, wherein the precursor is represented by

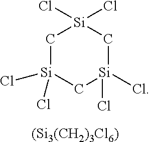

8. The method of claim 1, wherein each of the ALD cycles further comprises:
prior to pulsing the precursor to the dummy gate, pulsing a hydrogen gas to the dummy gate.

9. The method of claim 1, wherein each of the ALD cycles further comprises:
after pulsing the precursor to the dummy gate, pulsing a hydrogen gas to the dummy gate.

10. The method of claim 1, further comprising:
after forming the gate spacers on the opposite sidewalls of the dummy gate, performing a post treatment to the gate spacers using a thermal anneal, a UV cure or a remote plasma treatment.

11. A method of forming a semiconductor device, comprising:
forming a fin protruding from a substrate, wherein the fin comprises alternately stacked first semiconductor layers and second semiconductor layers;
etching sidewalls of the first semiconductor layers to form sidewall recesses between corresponding second semiconductor layers;
forming inner spacers in the sidewall recesses using one or more atomic layer deposition (ALD) cycles, wherein each of the ALD cycles comprises:
pulsing a precursor to the sidewall recesses, wherein the precursor comprises:
at least one Si atom;
at least one halogen atom; and
—CH₂— bond or —CH₃— bond;
forming epitaxial source/drain regions on opposite sides of the fin;
removing the first semiconductor layers to form spaces each between the second semiconductor layers; and
forming a metal gate wrapping around each of the second semiconductor layers.

12. The method of claim 11, wherein the precursor is represented by:
Si(CH₂)SiRₐX_{b} Formula (a1), and wherein in the formula (a1), R is H, Methyl (Me), Ethyl (Et), propyl (Pr), isopropyl (iPr), butyl (Bu), NMe2, NMeH, NH₂, NEt2, or NiPrH, X is Cl, Br, or I, a≥0, b≥0, and a+b=6.

13. The method of claim 11, wherein the precursor is represented by

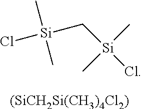

14. The method of claim 11, wherein the precursor is represented by:
Si(CH₂)₂SiRₓCl_{y} Formula (a2), and wherein in the formula (a2), R is H, Methyl (Me), Ethyl (Et), propyl (Pr), isopropyl (iPr), butyl (Bu), NMe2, NMeH, NH₂, NEt2, or NiPrH, X is Cl, Br, or I, a≥0, b≥0, and a+b=4.

15. The method of claim 11, wherein the precursor is represented by

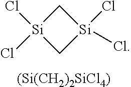

16. The method of claim 11, wherein the precursor is represented by:
Si₃(CH₂)₃RₓCl_{y} Formula (a3), and wherein in the formula (a3), R is H, Methyl (Me), Ethyl (Et), propyl (Pr), isopropyl (iPr), butyl (Bu), NMe2, NMeH, NH₂, NEt2, or NiPrH, X is Cl, Br, I, a≥0, b≥0, and a+b=6.

17. The method of claim 11, wherein the precursor is represented by

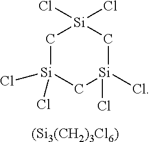

18. The method of claim 11, wherein pulsing the precursor to the sidewall recesses comprises:
pulsing the precursor at a temperature in a range from about 250° C. to about 400° C.

19. A semiconductor device, comprising:
a substrate;
a nanostructure protruding from the substrate, wherein the nanostructure has a surface comprising Si—O bonds;
a gate structure across the nanostructure; and
gate spacers extending along opposite sidewalls of the gate structure, wherein the gate spacers comprise a dielectric constant in a range from about 3.2 to about 5.2, and the gate spacers comprise Si—C—Si bonds to form a bridge structure connecting two neighboring Si—O bonds, and wherein C in the Si—C—Si bonds of the gate spacers is CH₂.

20. The semiconductor device of claim 19, further comprising:
epitaxial source/drain regions on opposite sides of the gate structure; and
inner spacers laterally between the gate structure and the epitaxial source/drain regions, wherein the inner spacers comprise Si—C—Si bonds to form a bridge structure connecting two neighboring Si—O bonds, and wherein C in the Si—C—Si bonds of the inner spacers is CH₂.
